(19) United States
(12) Patent Application Publication
(10) Pub. No.: US 2024/0179907 A1
(43) Pub. Date: May 30, 2024

(54) THREE-DIMENSIONAL MEMORY DEVICE CONTAINING ETCH STOP STRUCTURES FOR WORD LINE CONTACTS AND METHODS OF EMPLOYING THE SAME

(71) Applicant: SANDISK TECHNOLOGIES LLC, ADDISON, TX (US)

(72) Inventors: Hirofumi TOKITA, Yokkaichi (JP); Akihisa SAI, Yokkaichi (JP); Masato MIYAMOTO, Yokkaichi (JP)

(21) Appl. No.: 18/353,546

(22) Filed: Jul. 17, 2023

Related U.S. Application Data
(60) Provisional application No. 63/385,051, filed on Nov. 28, 2022.

(51) Int. Cl. H10B 43/27; H10B 41/27

(52) U.S. Cl. CPC H10B 43/27; H10B 41/27

(57) ABSTRACT

A method of making a semiconductor structure includes forming an alternating stack of insulating layers and sacrificial material layers, forming initial vertical stacks of at least one initial insulating plate and at least one initial dielectric material plate, and performing a plurality of pattern transfer process sequences that transfers the pattern of the initial vertical stacks by different numbers of underlying layers to form final vertical stacks of at least one final insulating plate and at least one final dielectric material plate. Sacrificial material layers that underlie the final vertical stacks are replaced with electrically conductive layers. The final dielectric material plates or conductive material plates formed by replacement of the dielectric material plates are employed as etch stop structures during subsequent formation of layer contact via structures.

### FIELD

The present disclosure relates generally to the field of semiconductor devices, and particularly to a three-dimensional memory device including etch stop structures for word line contacts and methods of employing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a method of forming a semiconductor structure is provided, which comprises: forming an alternating stack of insulating layers and sacrificial material layers over a substrate; forming a first patterned photoresist layer over the alternating stack, wherein the first patterned photoresist layer comprises a set of discrete photoresist material portions that are laterally spaced apart along a first horizontal direction; forming initial vertical stacks of at least one initial insulating plate and at least one initial dielectric material plate by transferring a pattern in the first patterned photoresist layer through at least one insulating layer within the insulating layers and at least one sacrificial material layer within the sacrificial material layers; performing a plurality of pattern transfer process sequences, wherein each of the plurality of pattern transfer process sequences comprises a respective patterned photoresist layer formation step that forms a respective patterned photoresist layer, a respective anisotropic etch process step that transfers a pattern in the respective patterned photoresist layer through at least one underlying insulating layer of the insulating layers and at least one sacrificial material layer of the sacrificial material layers, and a respective photoresist removal step that removes the respective patterned photoresist layer, wherein final vertical stacks of at least one final insulating plate and at least one final dielectric material plate are formed; and replacing remaining portions of the sacrificial material layers that underlie the final vertical stacks with electrically conductive layers.

According to another aspect of the present disclosure, a semiconductor structure is provided, which comprises: an alternating stack of insulating layers and electrically conductive layers, wherein the alternating stack comprises stepped surfaces; vertical stacks of at least one insulating plate and at least one spacer material plate, wherein each of the vertical stacks is located on a respective horizontal surface segment of the stepped surfaces; a dielectric material portion having a stepped bottom surface and contacting each of the vertical stacks; and layer contact via structures vertically extending through the dielectric material portion and a respective vertical stack of the vertical stacks and contacting a respective electrically conductive layer of the electrically conductive layers.

### BRIEF DESCRIPTION OF THE DRAWINGS

FIG. 1A is a vertical cross-sectional view of a first exemplary structure after formation of semiconductor devices, lower-level dielectric layers, lower-level metal interconnect structures, and in-process source-level material layers according to a first embodiment of the present disclosure.

FIG. 1B is a top-down view of the first exemplary structure of FIG. 1A. The vertical plane A-A′ is the plane of the vertical cross-sectional view of FIG. 1A.

FIG. 1C is a vertical cross-sectional view of the first exemplary structure along the vertical plane C-C′ of FIG. 1B.

FIG. 2 is a vertical cross-sectional view of the first exemplary structure after formation of a vertically alternating sequence of insulating layers and sacrificial material layers according to the first embodiment of the present disclosure.

FIG. 3 is a vertical cross-sectional view of the first exemplary structure after application and patterning of a first photoresist layer according to the first embodiment of the present disclosure.

FIG. 4 is a vertical cross-sectional view of the first exemplary structure after patterning a topmost insulating layer and a topmost sacrificial material layer according to the first embodiment of the present disclosure.

FIG. 5 is a vertical cross-sectional view of the first exemplary structure after removal of the first photoresist layer according to the first embodiment of the present disclosure.

FIG. 6 is a vertical cross-sectional view of the first exemplary structure after application and patterning of a second photoresist layer according to the first embodiment of the present disclosure.

FIG. 7 is a vertical cross-sectional view of the first exemplary structure after transferring a pattern in the second photoresist layer through a subset of underlying material layers according to the first embodiment of the present disclosure.

FIG. 8 is a vertical cross-sectional view of the first exemplary structure after trimming the second photoresist layer according to the first embodiment of the present disclosure.

FIG. 9 is a vertical cross-sectional view of the first exemplary structure after transferring a pattern in the trimmed second photoresist layer through a subset of underlying material layers according to the first embodiment of the present disclosure.

FIG. 10 is a vertical cross-sectional view of the first exemplary structure after removal of the trimmed second photoresist layer according to the second embodiment of the present disclosure.

FIG. 11 is a vertical cross-sectional view of the first exemplary structure after application and patterning of a third photoresist layer according to the first embodiment of the present disclosure.

FIG. 12 is a vertical cross-sectional view of the first exemplary structure after transferring a pattern in the third photoresist layer through a subset of underlying material layers according to the first embodiment of the present disclosure.

FIG. 13 is a vertical cross-sectional view of the first exemplary structure after removal of the third photoresist layer according to the first embodiment of the present disclosure.

FIG. 14 is a vertical cross-sectional view of the first exemplary structure after application and patterning of a fourth photoresist layer according to the first embodiment of the present disclosure.

FIG. 15 is a vertical cross-sectional view of the first exemplary structure after transferring a pattern in the fourth photoresist layer through a subset of underlying material layers according to the first embodiment of the present disclosure.

FIG. 16 is a vertical cross-sectional view of the first exemplary structure after removing the fourth photoresist layer according to the first embodiment of the present disclosure.

FIG. 17 is a vertical cross-sectional view of the first exemplary structure after application and patterning of a fifth photoresist layer according to the first embodiment of the present disclosure.

FIG. 18 is a vertical cross-sectional view of the first exemplary structure after transferring a pattern in the fifth photoresist layer through a subset of underlying material layers according to the first embodiment of the present disclosure.

FIG. 19 is a vertical cross-sectional view of the first exemplary structure after removing the fifth photoresist layer according to the first embodiment of the present disclosure.

FIG. 20 is a vertical cross-sectional view of the first exemplary structure after application and patterning of a sixth photoresist layer according to the first embodiment of the present disclosure.

FIG. 21 is a vertical cross-sectional view of the first exemplary structure after transferring a pattern in the sixth photoresist layer through a subset of underlying material layers according to the first embodiment of the present disclosure.

FIG. 22 is a vertical cross-sectional view of the first exemplary structure after removing the sixth photoresist layer according to the first embodiment of the present disclosure.

FIG. 23 is a vertical cross-sectional view of the first exemplary structure after formation of a retro-stepped dielectric material portion according to the first embodiment of the present disclosure.

FIG. 24 is a vertical cross-sectional view of the first exemplary structure after formation of memory openings according to the first embodiment of the present disclosure.

FIGS. 25A-25D are sequential vertical cross-sectional views of an inter-tier memory openings during formation of a memory opening fill structures according to the first embodiment of the present disclosure.

FIG. 26 is a vertical cross-sectional view of the first exemplary structure after formation of a contact-level dielectric layer according to the first embodiment of the present disclosure.

FIG. 27A is a vertical cross-sectional view of the first exemplary structure after formation of backside trenches according to the first embodiment of the present disclosure.

FIG. 27B is a top-down view of the first exemplary structure of FIG. 27A. The hinged vertical plane A-A′ is the plane of the vertical cross-section of FIG. 27A.

FIGS. 28A-28E illustrate sequential vertical cross-sectional views of a region of the first exemplary structure during formation of source-level material layers according to the first embodiment of the present disclosure.

FIG. 29 is a vertical cross-sectional view of the first exemplary structure after formation of the source-level material layers according to the first embodiment of the present disclosure.

FIG. 30 is a vertical cross-sectional view of the first exemplary structure after formation of backside recesses according to the first embodiment of the present disclosure.

FIG. 31 is a vertical cross-sectional view of the first exemplary structure after formation of electrically conductive layers in the backside recesses according to the first embodiment of the present disclosure.

FIG. 32 is a vertical cross-sectional view of the first exemplary structure after formation of backside trench fill structures according to the first embodiment of the present disclosure.

FIG. 33A is a vertical cross-sectional view of the first exemplary structure after formation of drain contact via structures and layer contact via structures according to the first embodiment of the present disclosure.

FIG. 33B is another vertical cross-sectional view of the first exemplary structure at the processing steps of FIG. 33A.

FIG. 34 is a vertical cross-sectional view of a second exemplary structure after formation of backside trench fill structures according to a second embodiment of the present disclosure.

FIG. 35 is a vertical cross-sectional view of the second exemplary structure after formation of drain contact via structures and layer contact via structures according to the second embodiment of the present disclosure.

FIG. 36 is a vertical cross-sectional view of a third exemplary structure according to a fourth embodiment of the present disclosure.

FIG. 37A is a vertical cross-sectional view of a fourth exemplary structure after formation of drain contact via structures and layer contact via structures according to a fifth embodiment of the present disclosure.

FIG. 37B is another vertical cross-sectional view of the fourth exemplary structure of FIG. 37A.

FIG. 38A is a vertical cross-sectional view of an exemplary structure after formation of a retro-stepped dielectric material portion according to various embodiments of the present disclosure.

FIG. 38B is a plan view of patterns for various photoresist material layers and backside trenches that can be employed to form the exemplary structure illustrated in FIG. 38A. The vertical plane A-A′ is the plane of the vertical cross-sectional view of FIG. 38A.

FIG. 39A is a plan view of a first exemplary semiconductor die including the structure of FIG. 38A according to various embodiments of the present disclosure.

FIG. 39B is a schematic see-through top-down view of region M1 of FIG. 39A.

### DETAILED DESCRIPTION

The present disclosure is directed to a three-dimensional memory device including etch stop structures for word line contacts and methods of employing the same, the various aspects of which are described in detail herebelow.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. As used herein, a first element located “on” a second element may be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

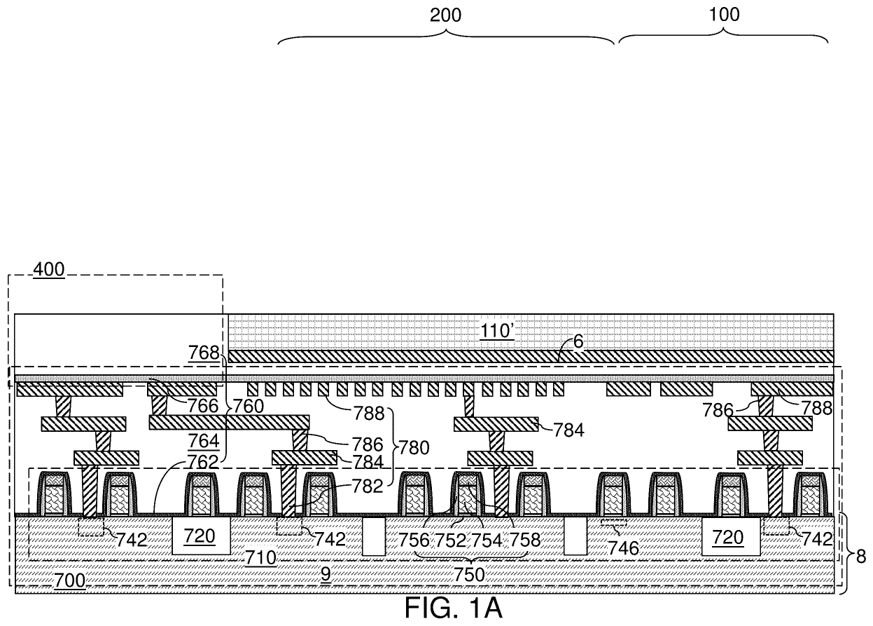

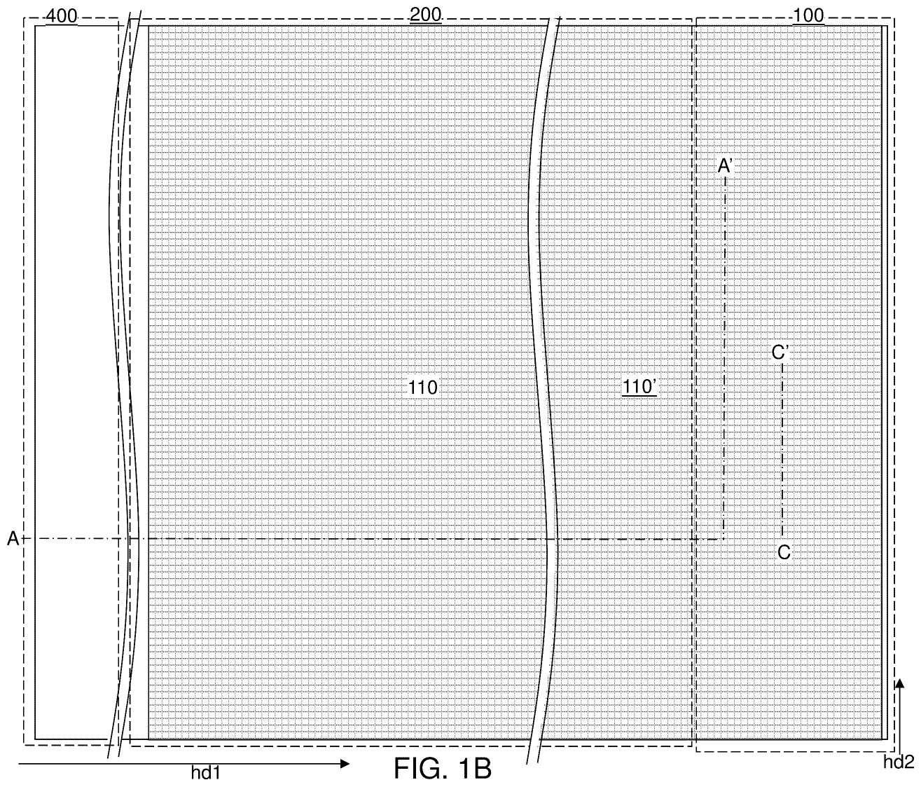

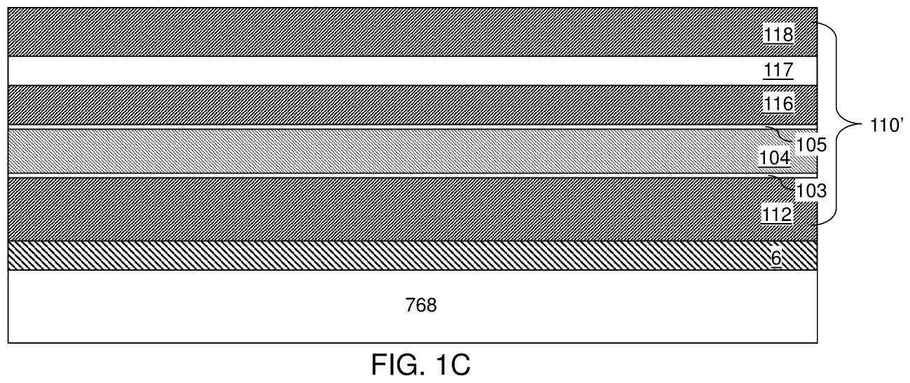

Referring to FIGS. 1A-1C, a first exemplary structure according to a first embodiment of the present disclosure is illustrated. The first exemplary structure includes a semiconductor substrate 8 and semiconductor devices 710 formed thereupon. In one embodiment, the semiconductor devices 710 may comprise a peripheral circuitry for controlling operation of a three-dimensional memory array to be subsequently formed. The first exemplary structure includes a memory array region 100 in which a three-dimensional memory array is to be subsequently formed, a staircase region 200 in which stepped surfaces of electrically conductive layers and contact via structures are to be subsequently formed, and a connection region 400 in which peripheral contact via structures are to be subsequently formed.

The substrate, such as a semiconductor substrate 8 includes a substrate semiconductor layer 9 at least at an upper portion thereof. The semiconductor substrate may comprise a silicon wafer and the substrate semiconductor layer 9 may comprise an upper portion of the silicon wafer containing various doped wells and/or an epitaxial silicon layer. Shallow trench isolation structures 720 can be formed in an upper portion of the substrate semiconductor layer 9 to provide electrical isolation among the semiconductor devices. The semiconductor devices 710 may include field effect transistors including respective transistor active regions 742 (i.e., source regions and drain regions), channel regions 746, and gate structures 750. The field effect transistors may be arranged in a CMOS configuration. Each gate structure 750 can include, for example, a gate dielectric 752, a gate electrode 754, a dielectric gate spacer 756 and a gate cap dielectric 758.

The semiconductor devices 710 can include additional semiconductor devices in addition to p-type field effect transistors and n-type field effect transistors, which can be employed to support operation of a memory structure to be subsequently formed. The semiconductor devices 710 may include a driver circuitry, which is also referred to as a peripheral circuitry. As used herein, a peripheral circuitry refers to any, each, or all, of word line decoder circuitry, word line switching circuitry, bit line decoder circuitry, bit line sensing and/or switching circuitry, power supply/distribution circuitry, data buffer and/or latch, or any other semiconductor circuitry that can be implemented outside a memory array structure for a memory device. For example, the semiconductor devices can include word line switching devices for electrically biasing word lines of three-dimensional memory structures to be subsequently formed.

Dielectric material layers are formed over the semiconductor devices, which are herein referred to as lower-level dielectric material layers 760. The lower-level dielectric material layers 760 can include, for example, a dielectric liner 762 (such as a silicon nitride liner that blocks diffusion of mobile ions and/or apply appropriate stress to underlying structures), first dielectric material layers 764 that overlie the dielectric liner 762, a silicon nitride layer (e.g., hydrogen diffusion barrier) 766 that overlies the first dielectric material layers 764, and at least one second dielectric layer 768.

The dielectric layer stack including the lower-level dielectric material layers 760 functions as a matrix for lower-level metal interconnect structures 780 that provide electrical wiring among the various nodes of the semiconductor devices and landing pads for through-memory-level contact via structures to be subsequently formed. The lower-level metal interconnect structures 780 are embedded within the dielectric layer stack of the lower-level dielectric material layers 760, and comprise a lower-level metal line structure located under and optionally contacting a bottom surface of the silicon nitride layer 766.

For example, the lower-level metal interconnect structures 780 can be embedded within the first dielectric material layers 764. The first dielectric material layers 764 may be a plurality of dielectric material layers in which various elements of the lower-level metal interconnect structures 780 are sequentially embedded. Each dielectric material layer among the first dielectric material layers 764 may include any of doped silicate glass, undoped silicate glass, organosilicate glass, silicon nitride, silicon oxynitride, and dielectric metal oxides (such as aluminum oxide). In one embodiment, the first dielectric material layers 764 can comprise, or consist essentially of, dielectric material layers having dielectric constants that do not exceed the dielectric constant of undoped silicate glass (silicon oxide) of 3.9. The lower-level metal interconnect structures 780 can include various device contact via structures 782 (e.g., source and drain electrodes which contact the respective source and drain nodes of the device or gate electrode contacts), intermediate lower-level metal line structures 784, lower-level metal via structures 786 and landing pads 788 for through-memory-level contact via structures to be subsequently formed.

The at least one second dielectric material layer 768 may include a single dielectric material layer or a plurality of dielectric material layers. Each dielectric material layer among the at least one second dielectric material layer 768 may include any of doped silicate glass, undoped silicate glass, and organosilicate glass. In one embodiment, the at least one second dielectric material layer 768 can comprise, or consist essentially of, dielectric material layers having dielectric constants that do not exceed the dielectric constant of undoped silicate glass (silicon oxide) of 3.9.

The semiconductor devices 710 can include peripheral devices for the memory-level assembly to be subsequently formed. The lower-level metal interconnect structures 780 are embedded in the lower-level dielectric layers 760. The combination of the lower-level dielectric layers 760 and the lower-level metal interconnect structures 780 overlie the semiconductor devices 710.

The lower-level metal interconnect structures 780 can be electrically connected to active nodes (e.g., transistor active regions 742 or gate electrodes 754) of the semiconductor devices 710 (e.g., CMOS devices), and are located at the level of the lower-level dielectric layers 760. Through-memory-level contact via structures can be subsequently formed directly on the lower-level metal interconnect structures 780 to provide electrical connection to memory devices to be subsequently formed.

In-process source-level material layers 110′ including a layer stack of material layers can be formed over lower-level dielectric layers 760. The in-process source-level material layers 110′ can include various layers that are subsequently modified to form source-level material layers. The source-level material layers, upon formation, include a source contact layer that functions as a common source region for vertical field effect transistors of a three-dimensional memory device. In one embodiment, the in-process source-level material layer 110′ can include, from bottom to top, a lower source-level material layer 112, a lower sacrificial liner 103, a source-level sacrificial layer 104, an upper sacrificial liner 105, an upper source-level material layer 116, a source-level insulating layer 117, and an optional source-select-level conductive layer 118.

The lower source-level material layer 112 and the upper source-level material layer 116 can include a doped semiconductor material such as doped polysilicon or doped amorphous silicon. The doped semiconductor material of the lower source-level material layer 112 is herein referred to as a first doped semiconductor material, and the doped semiconductor material of the upper source-level material layer 116 is herein referred to as a second doped semiconductor material, which may be the same or different from the first doped semiconductor material. The conductivity type of the lower source-level material layer 112 and the upper source-level material layer 116 can be the opposite of the conductivity of vertical semiconductor channels to be subsequently formed. For example, if the vertical semiconductor channels to be subsequently formed have a doping of a first conductivity type, the lower source-level material layer 112 and the upper source-level material layer 116 have a doping of a second conductivity type that is the opposite of the first conductivity type. The thickness of each of the lower source-level material layer 112 and the upper source-level material layer 116 can be in a range from 10 nm to 300 nm, such as from 20 nm to 150 nm, although lesser and greater thicknesses can also be employed.

The source-level sacrificial layer 104 includes a sacrificial material that can be removed selective to the lower sacrificial liner 103 and the upper sacrificial liner 105. In one embodiment, the source-level sacrificial layer 104 can include a dielectric material such as silicon nitride, or a semiconductor material such as undoped amorphous silicon or a silicon-germanium alloy with an atomic concentration of germanium greater than 20%. The thickness of the source-level sacrificial layer 104 can be in a range from 30 nm to 400 nm, such as from 60 nm to 200 nm, although lesser and greater thicknesses can also be employed.

The lower sacrificial liner 103 and the upper sacrificial liner 105 include materials that can function as an etch stop material during removal of the source-level sacrificial layer 104. For example, the lower sacrificial liner 103 and the upper sacrificial liner 105 can include silicon oxide, silicon nitride, and/or a dielectric metal oxide. In one embodiment, each of the lower sacrificial liner 103 and the upper sacrificial liner 105 can include a silicon oxide layer having a thickness in a range from 2 nm to 30 nm, although lesser and greater thicknesses can also be employed.

The source-level insulating layer 117 includes a dielectric material such as silicon oxide. The thickness of the source-level insulating layer 117 can be in a range from 20 nm to 400 nm, such as from 40 nm to 200 nm, although lesser and greater thicknesses can also be employed. The optional source-select-level conductive layer 118 can include a conductive material that can be employed as a source-select-level gate electrode. For example, the optional source-select-level conductive layer 118 can include a doped semiconductor material such as doped polysilicon or doped amorphous silicon that can be subsequently converted into doped polysilicon by an anneal process. The thickness of the optional source-level conductive layer 118 can be in a range from 30 nm to 200 nm, such as from 60 nm to 100 nm, although lesser and greater thicknesses can also be employed.

The in-process source-level material layers 110′ can be formed directly above a subset of the semiconductor devices 710 on the semiconductor substrate 8 (e.g., silicon wafer). As used herein, a first element is located “directly above” a second element if the first element is located above a horizontal plane including a topmost surface of the second element and an area of the first element and an area of the second element has an areal overlap in a plan view (i.e., along a vertical plane or direction perpendicular to the top surface of the substrate 8.

The in-process source-level material layers 110′ may be patterned to provide openings in areas in which through-memory-level contact via structures and through-dielectric contact via structures are to be subsequently formed. Patterned portions of the in-process source-level material layers 110′ are present in each memory array region 100 in which three-dimensional memory stack structures are to be subsequently formed. The at least one second dielectric material layer 768 can include a blanket layer portion underlying the in-process source-level material layers 110′ and a patterned portion that fills gaps among the patterned portions of the in-process source-level material layers 110′.

The in-process source-level material layers 110′ can be patterned such that an opening extends over a staircase region 200 in which contact via structures contacting word line electrically conductive layers are to be subsequently formed. In one embodiment, the staircase region 200 can be laterally spaced from the memory array region 100 along a first horizontal direction hd1. A horizontal direction that is perpendicular to the first horizontal direction hd1 is herein referred to as a second horizontal direction hd2.

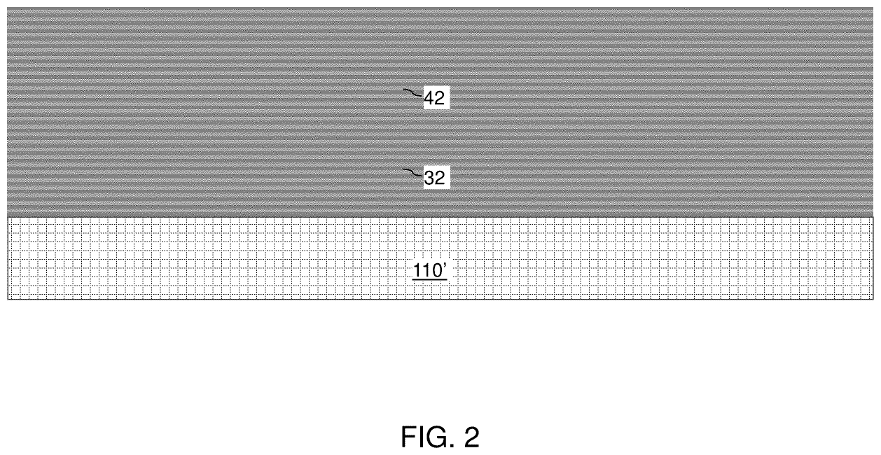

Referring to FIG. 2, a vertically alternating sequence of insulating layers 32 and sacrificial material layers 42 is formed over the in-process source-level material layers 110′. The vertically alternating sequence of insulating layers 32 and sacrificial material layers 42 is also referred to as an alternating stack. Each insulating layer 32 can include an insulating material, and each sacrificial material layer 42 can include a sacrificial material. The sacrificial material layers 42 are subsequently replaced with electrically conductive layers. As used herein, a “sacrificial material” refers to a material that is removed during a subsequent processing step.

The alternating stack (32, 42) can include insulating layers 32 composed of the first material, and sacrificial material layers 42 composed of the second material, which is different from the first material. The first material of the insulating layers 32 can be at least one insulating material. Insulating materials that can be employed for the insulating layers 32 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The second material of the sacrificial material layers 42 is a sacrificial material that can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise an insulating material, a semiconductor material, or a conductive material. The second material of the sacrificial material layers 42 can be subsequently replaced with electrically conductive electrodes which can function, for example, as control gate electrodes of a vertical NAND device. In one embodiment, the sacrificial material layers 42 can be material layers that comprise silicon nitride.

In one embodiment, the insulating layers 32 can include silicon oxide, and sacrificial material layers can include silicon nitride sacrificial material layers. The first material of the insulating layers 32 can be deposited, for example, by chemical vapor deposition (CVD). For example, if silicon oxide is employed for the insulating layers 32, tetraethylorthosilicate (TEOS) can be employed as the precursor material for the CVD process. The second material of the sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be employed for each insulating layer 32 and for each sacrificial material layer 42. The number of repetitions of the pairs of a insulating layer 32 and a sacrificial material layer 42 can be in a range from 2 to 1,024, and typically from 8 to 256, although a greater number of repetitions can also be employed. In one embodiment, each sacrificial material layer 42 in the alternating stack (32, 42) can have a uniform thickness that is substantially invariant within each respective sacrificial material layer 42.

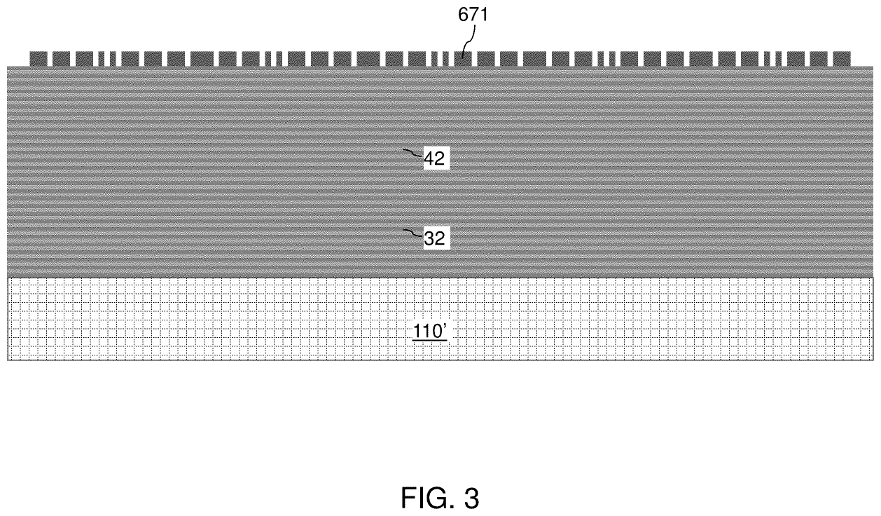

Referring to FIG. 3, a first photoresist layer 671 can be applied over the alternating stack (32, 42), and can be lithographically patterned into a plurality of discrete photoresist material portion having straight edges that are perpendicular to the first horizontal direction hd1 and parallel to the second horizontal direction hd2. In one embodiment, each discrete portion of the first patterned photoresist layer 671 may cover a respective area in which at least one respective layer contact via structure is to be subsequently formed. Generally, the first patterned photoresist layer 671 comprises a set of discrete photoresist material portions that are laterally spaced apart along a first horizontal direction hd1. The first patterned photoresist layer 671 covers the entirety of the memory array region 100 in which memory stack structures are to be subsequently formed.

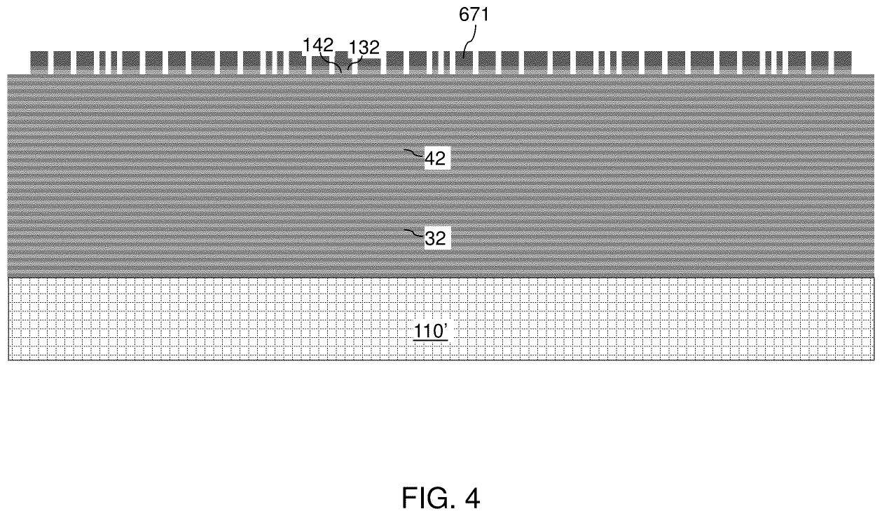

Referring to FIG. 4, a first anisotropic etch process can be performed to etch unmasked portions of the topmost sacrificial material layer 42 and the topmost insulating layer 32, i.e., the topmost one of the sacrificial material layers 42 and the topmost one of the insulating layers 32. Each patterned portion of the topmost sacrificial material layer 42 is herein referred to as an initial dielectric material plate 142. Each patterned portion of the topmost insulating layer 32 is herein referred to as an initial insulating plate 132. Each contiguous combination of an initial dielectric material plate 142 and an initial insulating plate 132 is herein referred to as an initial vertical stack (132, 142). The initial vertical stacks (132, 142) of a respective initial insulating plate 132 and a respective initial dielectric material plate 142 can be formed by transferring a pattern in the first patterned photoresist layer 671 through the topmost insulating layer 32 and through the topmost sacrificial material layer 42.

In one embodiment, the initial vertical stacks (132, 142) of a respective initial insulating plate 132 and a respective initial dielectric material plate 142 may be arranged in rows that laterally extend along the first horizontal direction hd1. The initial vertical stacks (132, 142) within each row of initial vertical stacks (132, 142) may be arranged along the first horizontal direction hd1, and the rows of initial vertical stacks (132, 142) may be laterally spaced apart along the second horizontal direction hd2. In one embodiment, the total number of initial vertical stacks (132, 142) within each row of initial vertical stacks (132, 142) may be the same as or may be greater than the total number of the sacrificial material layers 42 within the vertically alternating sequence (32, 242) as formed at the processing steps of FIG. 2.

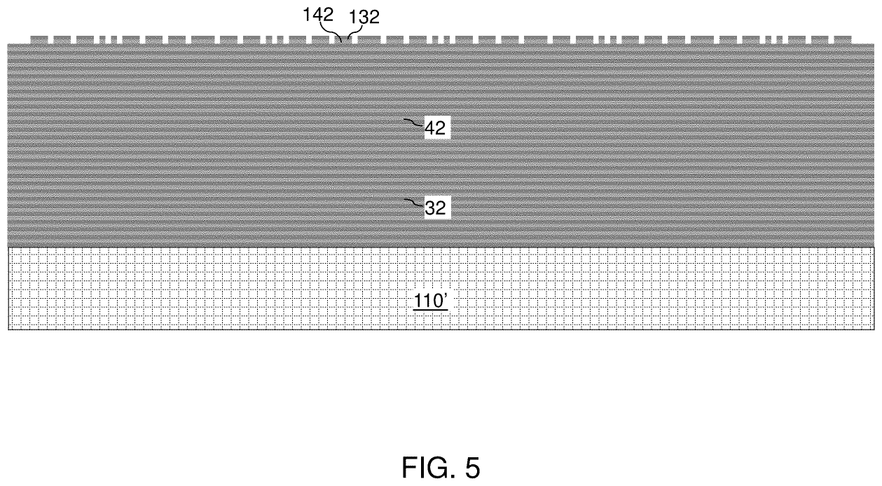

Referring to FIG. 5, the first patterned photoresist layer 671 can be removed selective to the materials of the alternating stack (32, 42) and the initial vertical stacks (132, 142) by performing an ashing process.

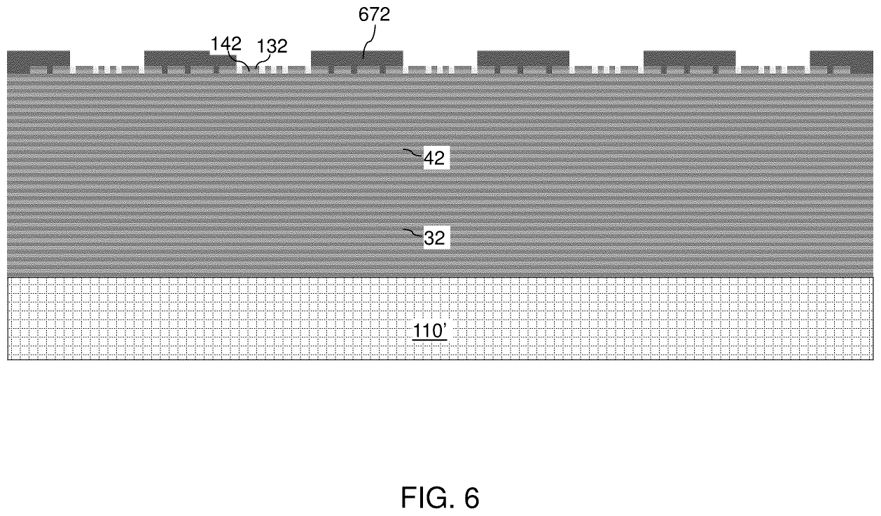

Referring to FIG. 6, a second photoresist layer 672 can be applied over the alternating stack (32, 42) and the initial vertical stacks (132, 142), and can be lithographically patterned into a plurality of discrete photoresist material portion having straight edges that are perpendicular to the first horizontal direction hd1 and parallel to the second horizontal direction hd2. In one embodiment, the second photoresist layer 672 may be a trimmable photoresist material layer, i.e., a photoresist material layer that may be isotropically trimmed at a controlled trimming rate during a trimming process such as a low temperature ashing process. In one embodiment, each discrete portion of the second patterned photoresist layer 672 may cover a respective subset of the initial vertical stacks (132, 142). The discrete photoresist material portions of the second photoresist layer 672 can cover a first subset of the initial vertical stacks (132, 142) without covering a first complementary subset of the initial vertical stacks (132, 142), i.e., without covering the initial vertical stacks (132, 142) that do not being to the first subset of the initial vertical stacks (132, 142). The number of the initial vertical stacks (132, 142) within the first subset of the initial vertical stacks (132, 142) may be in a range from 25% to 75% of the total number of the initial vertical stacks (132, 142), and/or in a range from 40% to 60% of the total number of the initial vertical stacks (132, 142), although lesser and greater percentages may also be employed. Generally, the second patterned photoresist layer 672 comprises a set of discrete photoresist material portions that are laterally spaced apart along the horizontal direction hd1, and covers at least one and/or a respective plurality of the initial vertical stacks (132, 142). In the illustrated example, each discrete photoresist material portion the second patterned photoresist layer 672 covers a respective set of four initial vertical stacks (132, 142). The second patterned photoresist layer 672 covers the entirety of the memory array region 100 in which memory stack structures are to be subsequently formed.

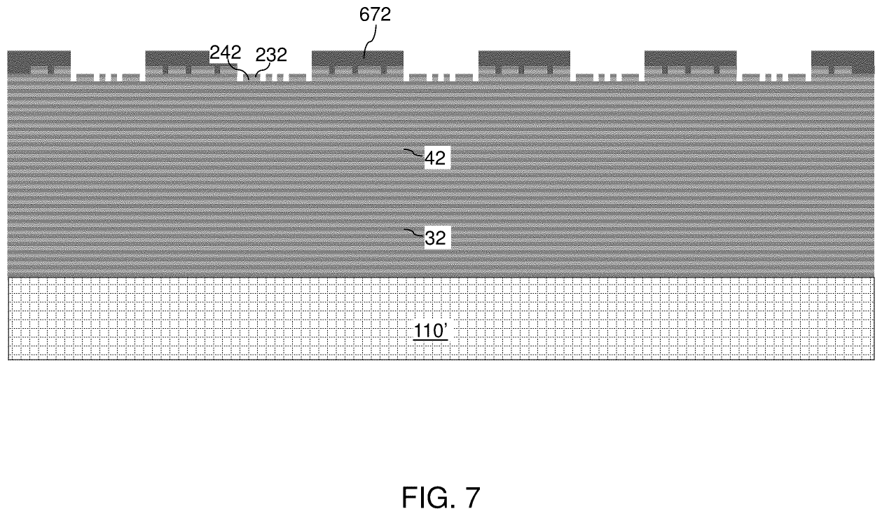

Referring to FIG. 7, a second anisotropic etch process can be performed to etch portions of a sacrificial material layer 42 and an insulating layer 32 within each area that is not masked by the second patterned photoresist layer 672. In this case, unmasked portions of a second-from-the top sacrificial material layer 42 and a second-from-the-top insulating layer 32 can be etched by the second anisotropic etch process within each area that is not covered by the second patterned photoresist layer 672. The second-from-the-top sacrificial material layer 42 refers to the second sacrificial material layer 42 as counted from top to bottom within the alternating stack (32, 42) at the processing steps of FIG. 2. The second-from-the-top insulating layer 32 refers to the second insulating layer 32 as counted from top to bottom within the alternating stack (32, 42) at the processing steps of FIG. 2. Each patterned portion of the sacrificial material layers 42 is herein referred to as an intermediate dielectric material plate 242. Each patterned portion of the insulating layers 32 is herein referred to as an intermediate insulating plate 232. Each contiguous combination of an intermediate dielectric material plate 242 and an intermediate insulating plate 232 is herein referred to as an intermediate vertical stack (232, 242). The intermediate vertical stacks (232, 242) of a respective initial insulating plate 232 and a respective initial dielectric material plate 242 can be formed by transferring the pattern in the first photoresist layer 671 and the pattern in the second patterned photoresist layer 672 through two or more insulating layers 32 including the topmost insulating layer 32 and through two or more insulating layers including the topmost sacrificial material layer 42.

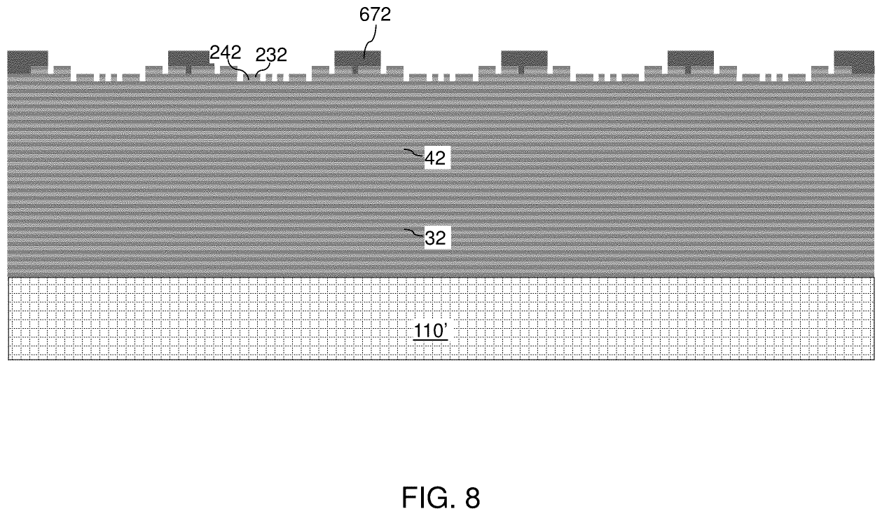

Referring to FIG. 8, the second patterned photoresist layer 672 can be trimmed by performing a trimming process such as an ashing process providing a controlled ashing rate. The second patterned photoresist layer 672 can be trimmed until each patterned photoresist material portion of the second patterned photoresist layer 672 covers a lesser number of intermediate vertical stack (232, 242) than the number of initial vertical stacks (132, 142) covered by the untrimmed second patterned photoresist layer 672 at the processing steps of FIG. 6. In one embodiment, the number of the intermediate vertical stacks (232, 242) that are covered by the trimmed second patterned photoresist layer 672 may be in a range from 20% to 60% of the total number of the intermediate vertical stacks (232, 242), and/or in a range from 12.5% to 50% of the total number of the intermediate vertical stacks (232, 242), although lesser and greater percentages may also be employed.

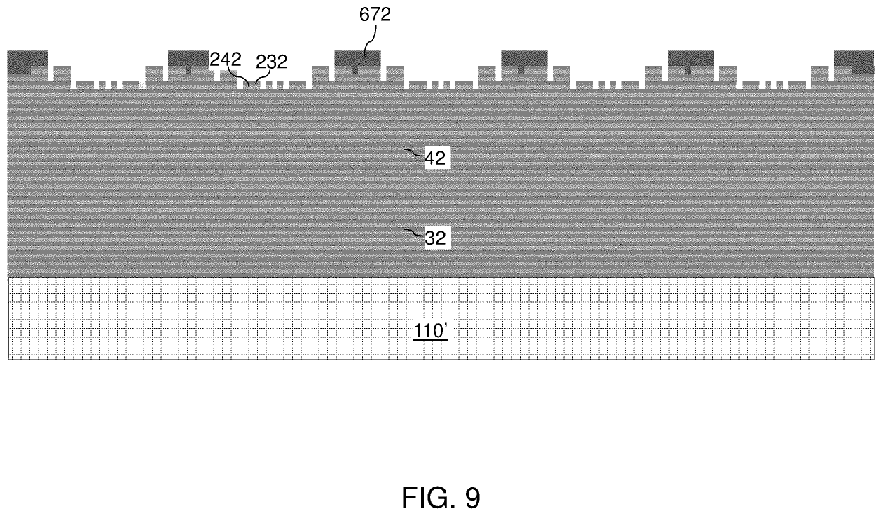

Referring to FIG. 9, an additional anisotropic etch process can be performed to etch portions of a sacrificial material layer 42 and an insulating layer 32 within each area that is not masked by the second patterned photoresist layer 672. In this case, unmasked portions of a second-from-the top sacrificial material layer 42 and a second-from-the-top insulating layer 32 can be etched by the additional anisotropic etch process within each area that is not covered by the second patterned photoresist layer 672. The pattern of the intermediate vertical stacks (232, 242) can shift downward by a vertical distance that equals the sum of the thickness of an insulating layer 32 and the thickness of a sacrificial material layer 42 within each area that is not covered by the trimmed second patterned photoresist layer 672. The pattern of the intermediate vertical stacks (232, 242) does not change within each area that is covered by the trimmed second patterned photoresist layer 672.

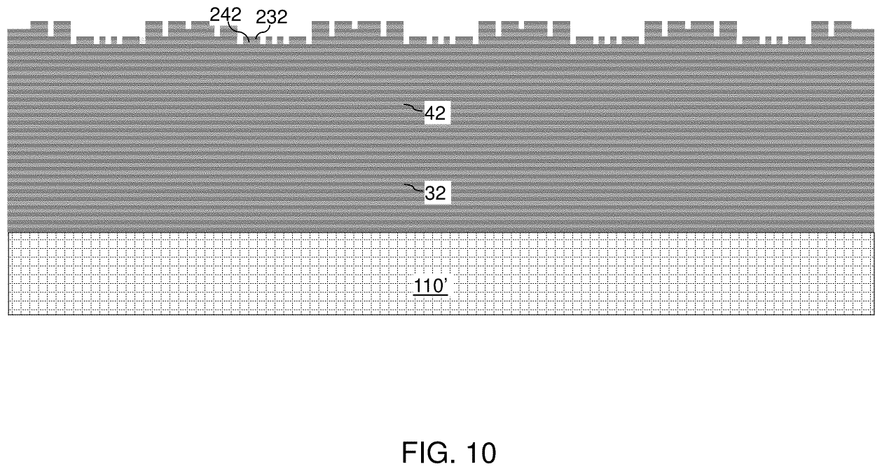

Referring to FIG. 10, the second patterned photoresist layer 672 can be removed selective to the materials of the alternating stack (32, 42) and the intermediate vertical stacks (232, 242) by performing an ashing process. The combination of processing steps described with reference to FIGS. 6-10 constitute a first pattern transfer process sequence including a patterned photoresist layer formation step that applies the second patterned photoresist layer 672 (such as the processing step described with reference to FIG. 6), a second anisotropic etch step that transfers the pattern in the second patterned photoresist layer 672 through at least one underlying insulating layer 32 and at least one underlying sacrificial material layer 42 (such as the processing step described with reference to FIG. 7), and a photoresist removal step that removes the second patterned photoresist layer (such as the processing step described with reference to FIG. 10). At least one photoresist layer trimming process step and at least one additional anisotropic etch step may be optionally performed during the first pattern transfer process sequence.

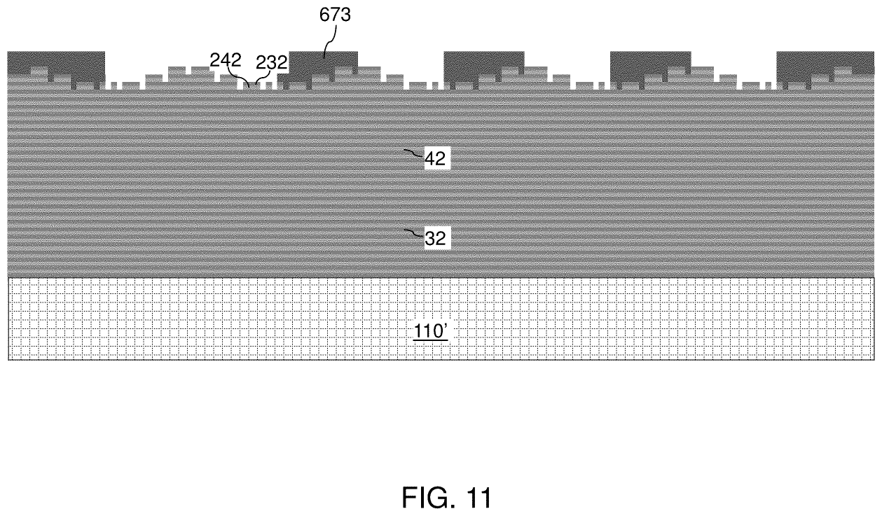

Referring collectively to FIGS. 11-22, a plurality of pattern transfer process sequences can be performed to transfer components of the pattern of the intermediate vertical stacks (232, 242) into underlying insulating layers 32 and underlying sacrificial material layers 42 by different vertical pattern shift distances. Each of the plurality of pattern transfer process sequences comprises a respective patterned photoresist layer formation step that forms a respective patterned photoresist layer (672, 673, 674, 675, 676), a respective anisotropic etch process step that transfers a pattern in the respective patterned photoresist layer (672, 673, 674, 675, 676) through at least one underlying insulating layer 32 among the insulating layers 32 and at least one sacrificial material layer 42 among the sacrificial material layers 42, and a respective photoresist removal step that removes the respective patterned photoresist layer (672, 673, 674, 675, 676). Each vertical stack of a respective insulating plate and a respective dielectric material plate after the final pattern transfer process sequence is referred to as a final vertical stacks (332, 342) of a final insulating plate 332 and a final dielectric material plate 342.

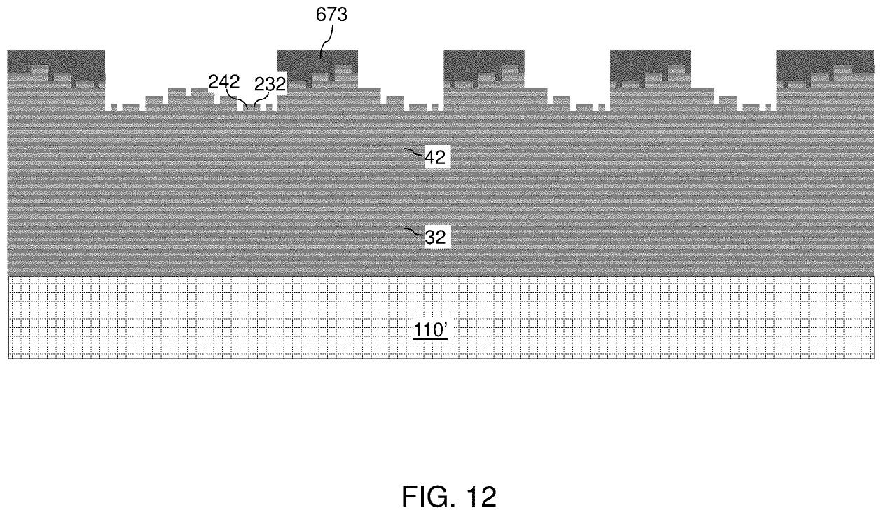

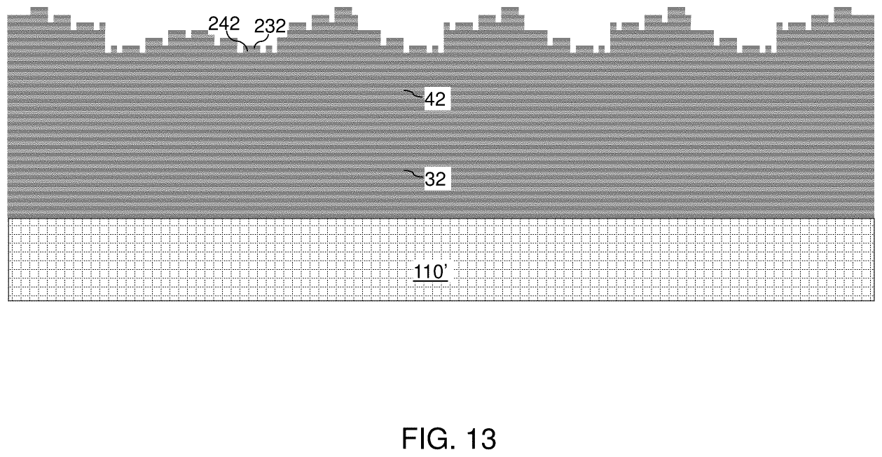

FIG. 11 is a vertical cross-sectional view of the first exemplary structure after application and patterning of a third photoresist layer 673 according to the first embodiment of the present disclosure. FIG. 12 is a vertical cross-sectional view of the first exemplary structure after transferring a pattern in the third photoresist layer 673 through a subset of underlying material layers according to the first embodiment of the present disclosure. FIG. 13 is a vertical cross-sectional view of the first exemplary structure after removal of the third photoresist layer 673 according to the first embodiment of the present disclosure.

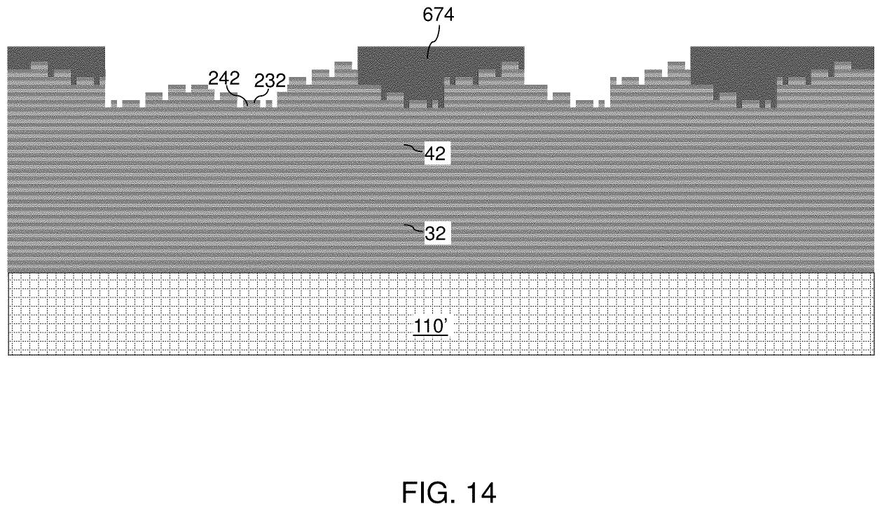

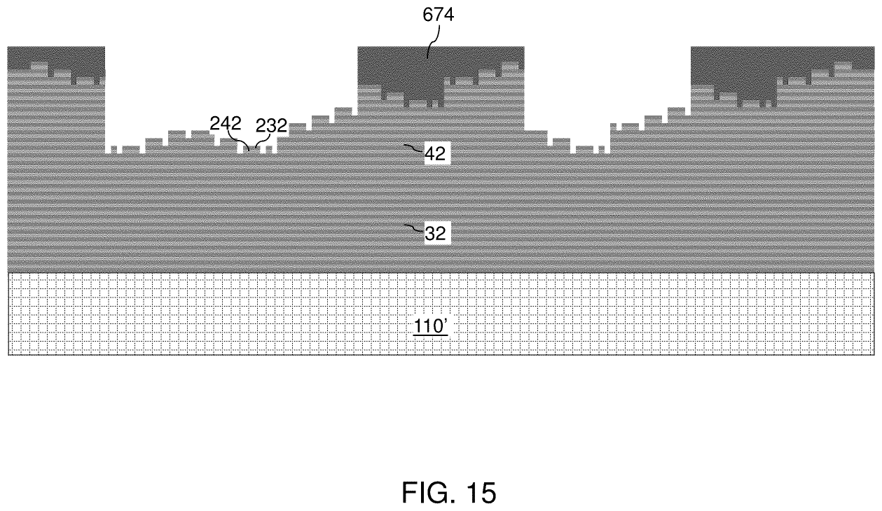

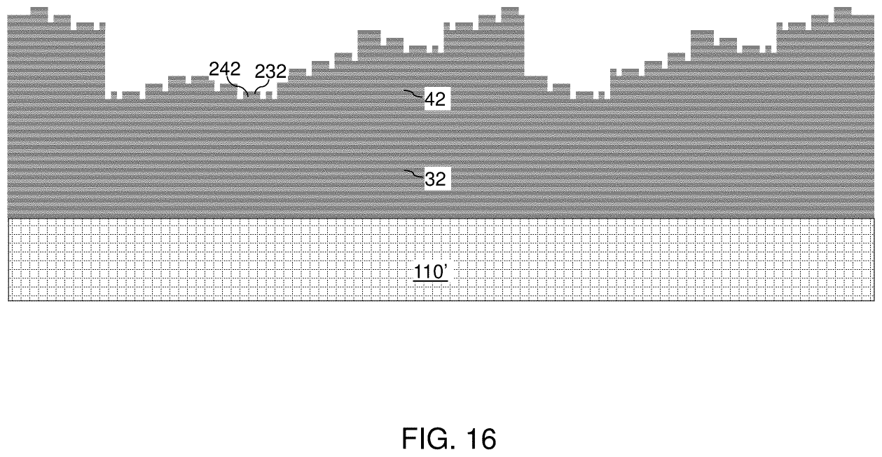

FIG. 14 is a vertical cross-sectional view of the first exemplary structure after application and patterning of a fourth photoresist layer 674 according to the first embodiment of the present disclosure. FIG. 15 is a vertical cross-sectional view of the first exemplary structure after transferring a pattern in the fourth photoresist layer 674 through a subset of underlying material layers according to the first embodiment of the present disclosure. FIG. 16 is a vertical cross-sectional view of the first exemplary structure after removing the fourth photoresist layer 674 according to the first embodiment of the present disclosure.

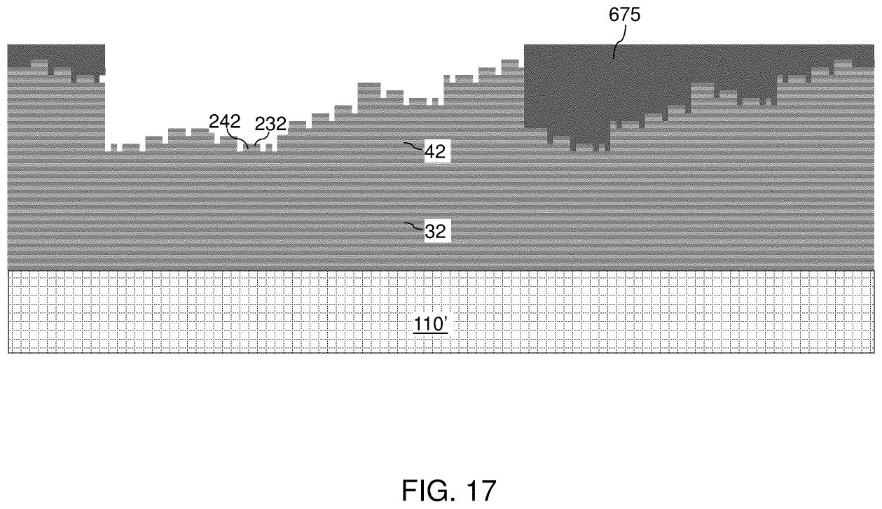

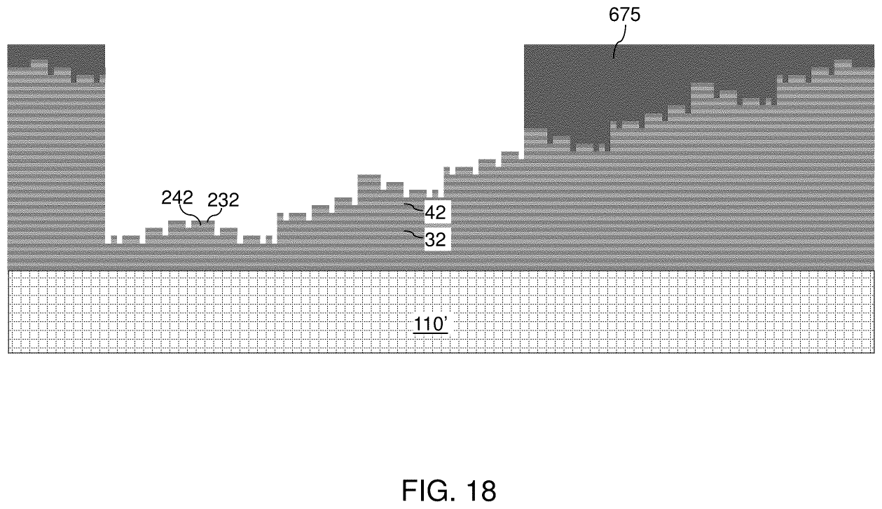

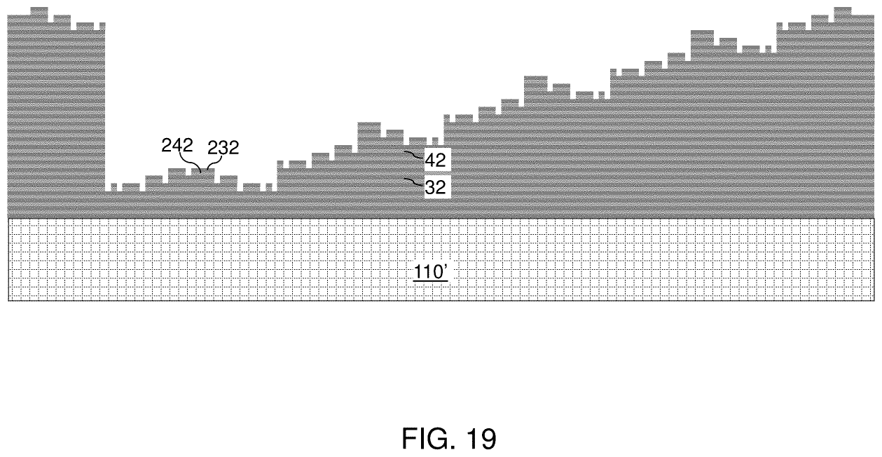

FIG. 17 is a vertical cross-sectional view of the first exemplary structure after application and patterning of a fifth photoresist layer 675 according to the first embodiment of the present disclosure. FIG. 18 is a vertical cross-sectional view of the first exemplary structure after transferring a pattern in the fifth photoresist layer 675 through a subset of underlying material layers according to the first embodiment of the present disclosure. FIG. 19 is a vertical cross-sectional view of the first exemplary structure after removing the fifth photoresist layer 675 according to the first embodiment of the present disclosure.

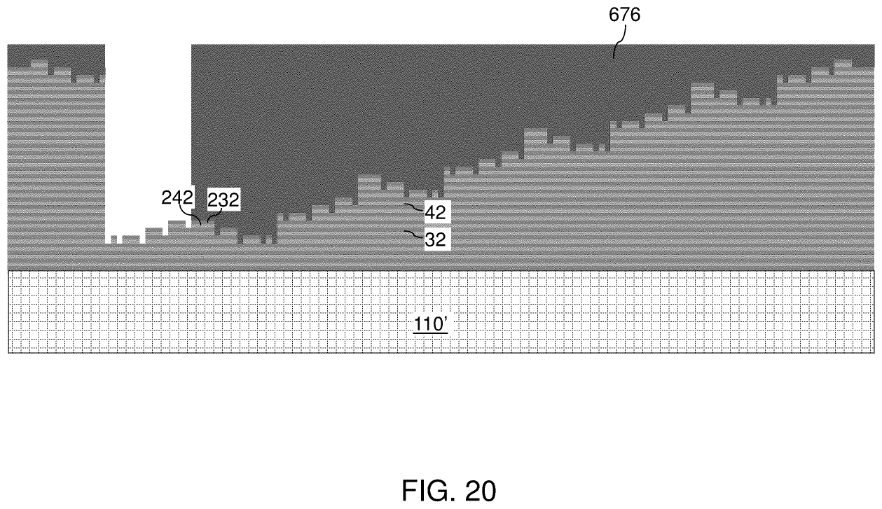

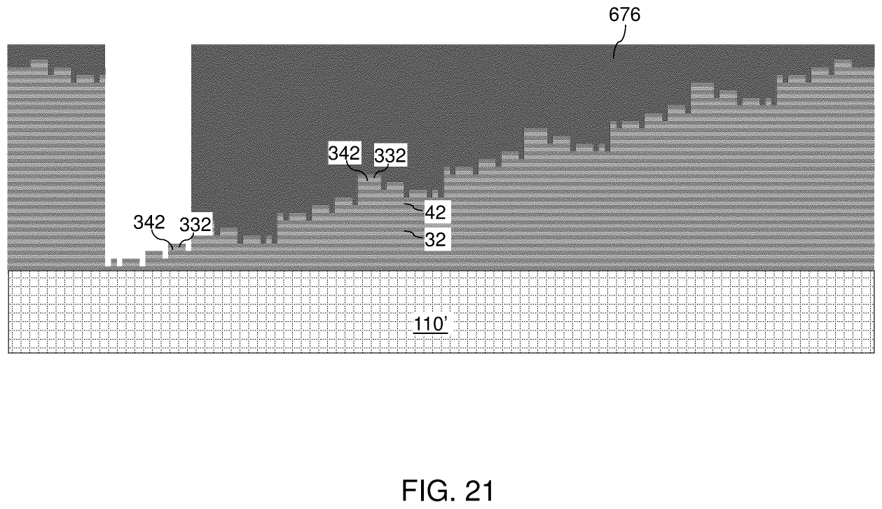

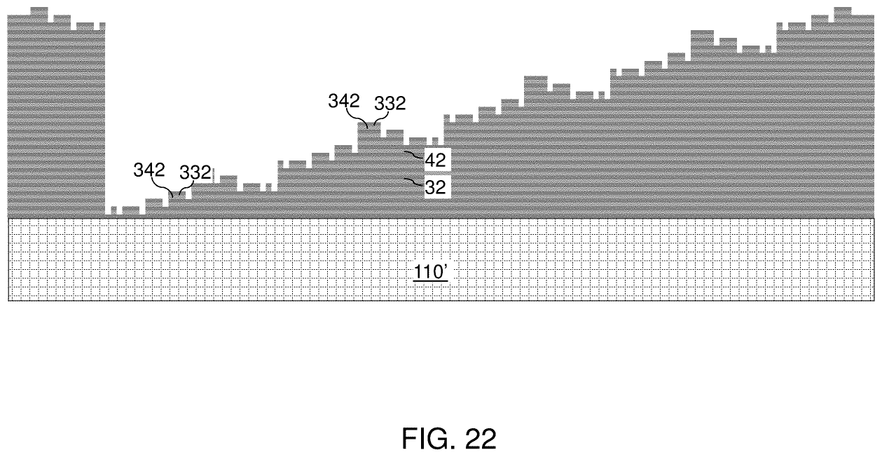

FIG. 20 is a vertical cross-sectional view of the first exemplary structure after application and patterning of a sixth photoresist layer 676 according to the first embodiment of the present disclosure. FIG. 21 is a vertical cross-sectional view of the first exemplary structure after transferring a pattern in the sixth photoresist layer 676 through a subset of underlying material layers according to the first embodiment of the present disclosure. FIG. 22 is a vertical cross-sectional view of the first exemplary structure after removing the sixth photoresist layer 676 according to the first embodiment of the present disclosure.

Generally, each anisotropic etch process step within the pattern transfer process sequences may transfer the pattern in a respective patterned photoresist layer (672, 673, 674, 675, 676) through a respective number of pairs of underlying insulating layers 32 and underlying sacrificial material layers 42. In one embodiment, the numbers of pairs of underlying insulating layers 32 and underlying sacrificial material layers 42 may be non-negative powers of 2, such as 1, 2, 4, 8, 16, 32, 64, etc. The initial vertical stacks (132, 142) as provided after the processing steps of FIG. 5 are covered by different combinations of the patterned photoresist material layers during the anisotropic etch step processes by selecting the patterns of the patterned photoresist material layers. The final vertical stacks (332, 342) of a respective final insulating plate 332 and a respective final dielectric material plate 342 can be formed at each level of the insulating layers 32 and the sacrificial material layers 42 other than the levels of the bottommost insulating layer 32 and the bottommost sacrificial material layer 42. Stepped surfaces of the insulating layers 32 and the sacrificial material layers 42 can be formed in the staircase region 200. The final vertical stacks (332, 342) of a respective final insulating plate 332 and a respective final dielectric material plate 342 can be formed over the stepped surfaces of the insulating layers 32 and the sacrificial material layers 42. The cavity overlying the stepped surfaces and the final vertical stacks (332, 342) is herein referred to as a stepped cavity.

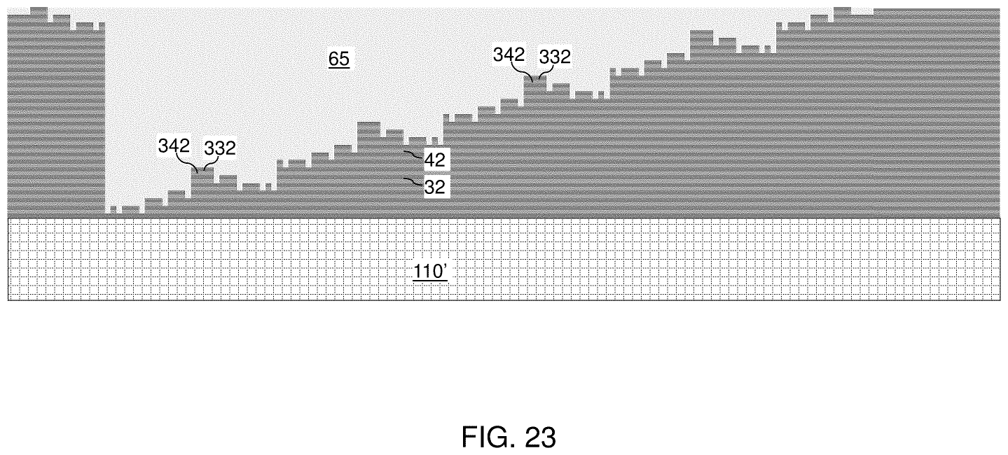

Referring to FIG. 23, a planarizable dielectric fill material (such as undoped silicate glass or a doped silicate glass) can be deposited in the stepped cavity over the stepped surfaces of the alternating stack (32, 42) and the final vertical stacks (332, 342). A planarization process can be performed to remove an excess portion of the planarizable dielectric material from above the horizontal plane including the topmost surface of the alternating stack (32, 42). The planarization process may comprise a recess etch process and/or a chemical mechanical polishing (CMP) process. A remaining dielectric material portion of the planarizable dielectric fill material filling the stepped cavity is herein referred to as a stepped dielectric material portion 65 or a retro-stepped dielectric material portion 65 (i.e., a dielectric material portion having a stepped surface as a bottom surface). The stepped bottom surface of the stepped dielectric material portion 65 can be formed directly on the final vertical stacks (332, 342) of at least one final insulating plate 332 and at least one final dielectric material plate 342.

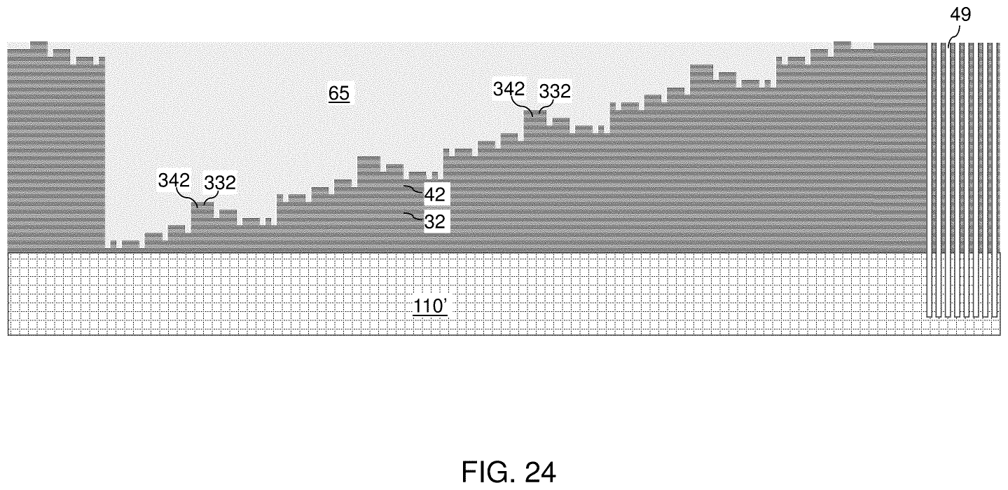

Referring to FIG. 24, memory openings 49 can be formed in the memory array region 100 through the alternating stack (32, 42) and partly through the in-process source-level material layers 110′. For example, a photoresist layer (not shown) can be applied over the alternating stack (32, 42) and the stepped dielectric material portion 65, and can be lithographically patterned to form openings in the memory array region 100. The pattern of openings in the photoresist layer can be transferred through the alternating stack (32, 42) and partly through the in-process source-level material layers 110′ by performing an anisotropic etch process.

The memory openings 49 are formed in the memory array region 100 through each layer within the alternating stack (32, 42) and are subsequently employed to form memory stack structures therein. The bottom surfaces of the memory openings 49 can be a recessed surface of the source-level sacrificial layer 104. Thus, each memory opening 49 can have a bottom surface between a horizontal plane including the bottom surface of the source-level sacrificial layer 104 and a horizontal plane including the top surface of the source-level sacrificial layer 104. In one embodiment, bottom surfaces of the memory openings 49 may be formed within the lower source-level material layer 112. In one embodiment, the memory openings 149 can be formed as clusters that are laterally spaced apart from each other along the second horizontal direction hd2. Each cluster of memory openings 49 can include a respective two-dimensional array of memory openings 49 having a first pitch along one horizontal direction (such as the first horizontal direction hd1) and a second pitch along another horizontal direction (such as the second horizontal direction hd2). The memory array region 100 can be free of any stepped surfaces and free of final vertical stacks (332, 342). Generally, the memory openings 49 can be formed through a region of the alternating stack (32, 42) that is free of the final vertical stacks (332, 342).

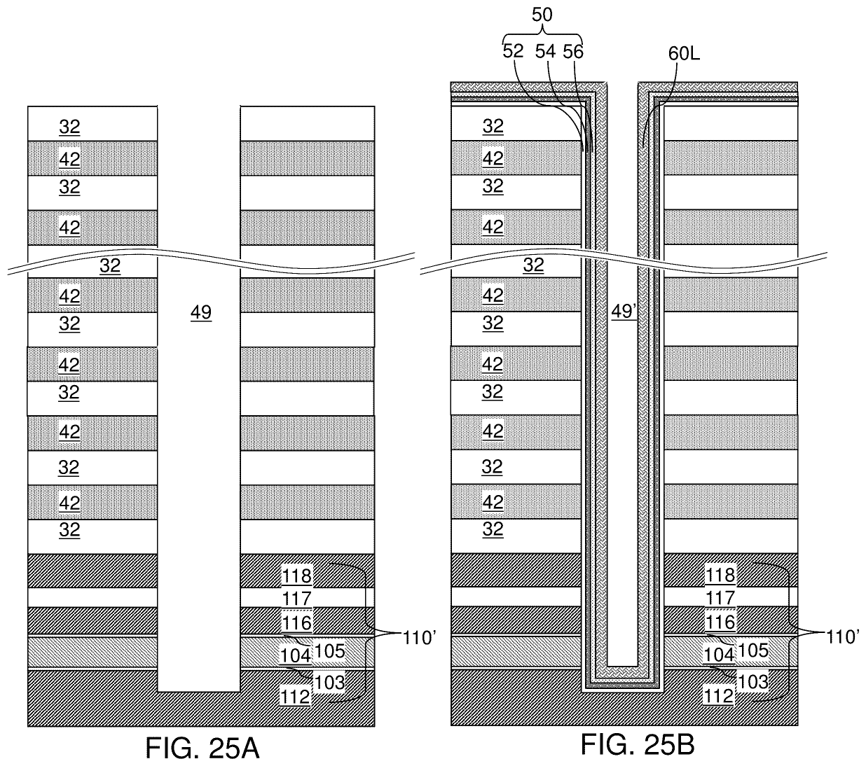

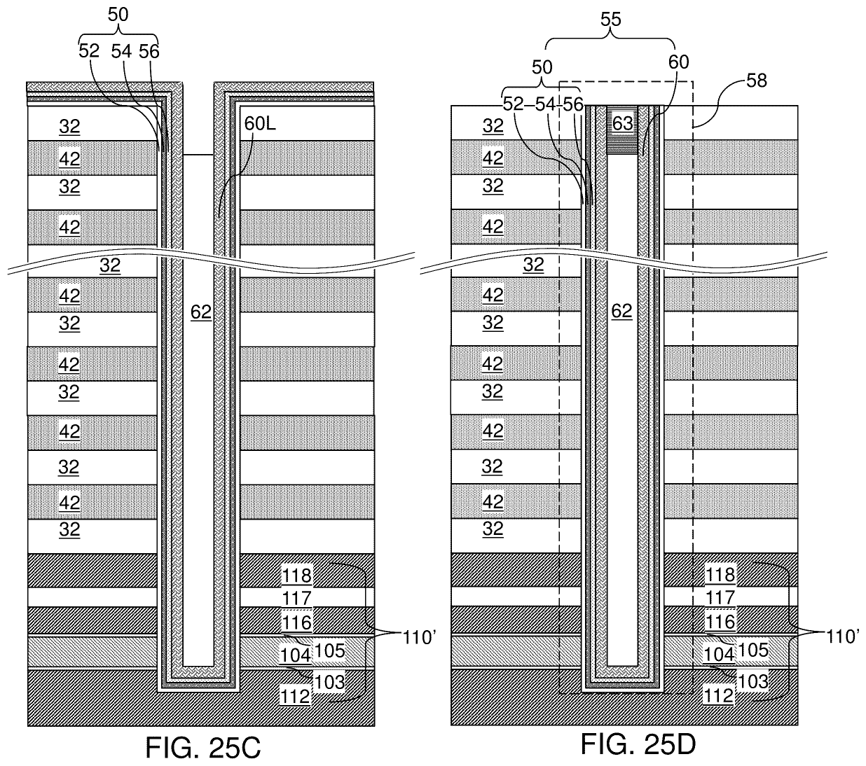

FIGS. 25A-25D are sequential vertical cross-sectional views of an inter-tier memory openings 49 during formation of a memory opening fill structure 58 according to the first embodiment of the present disclosure. Referring to FIG. 25A, a memory opening 49 in the first exemplary device structure of FIG. 24 is illustrated. The memory opening 49 extends through the first-tier structure and the second-tier structure.

Referring to FIG. 25B, a stack of layers including an optional blocking dielectric layer 52, a memory material layer 54, an optional dielectric isolation liner 56, and a semiconductor channel material layer 60L can be sequentially deposited in the memory openings 49. The blocking dielectric layer 52 can include a single dielectric material layer or a stack of a plurality of dielectric material layers. In one embodiment, the blocking dielectric layer can include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 can include a dielectric metal oxide having a dielectric constant greater than 7.9, i.e., having a dielectric constant greater than the dielectric constant of silicon nitride. The thickness of the dielectric metal oxide layer can be in a range from 1 nm to 20 nm, although lesser and greater thicknesses can also be employed. The dielectric metal oxide layer can subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 can include a dielectric semiconductor compound such as silicon oxide, silicon oxynitride, silicon nitride, or a combination thereof.

Subsequently, the memory material layer 54 can be formed. the memory material layer may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a charge storage layer or patterned discrete portions of a charge trapping material including a dielectric charge trapping material, which can be, for example, silicon nitride. Alternatively or additionally, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer.

In another embodiment, the sacrificial material layers 42 can be laterally recessed with respect to the sidewalls of the insulating layers 32, and a combination of a deposition process and an anisotropic etch process can be employed to form the memory material layer 54 as a plurality of memory material portions that are vertically spaced apart. While an embodiment in which the memory material layer 54 is a single continuous layer is described, other embodiments are expressly contemplated herein in which the memory material layer 54 is replaced with a plurality of discrete memory material portions (which can be charge trapping material portions or electrically isolated conductive material portions) that are vertically spaced apart. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

The optional dielectric isolation layer 56, if present, comprises a material that can provide electrical isolation between the memory material layer 54 and the semiconductor channel material layer 60L. In one embodiment, the dielectric isolation liner 56 comprises a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric isolation liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric isolation liner 56 can include a stack of a first silicon oxide layer, a silicon oxynitride layer, and a second silicon oxide layer, which is commonly known as an ONO stack. In one embodiment, the dielectric isolation liner 56 can include a silicon oxide layer that is substantially free of carbon or a silicon oxynitride layer that is substantially free of carbon. The thickness of the dielectric isolation liner 56 can be in a range from 2 nm to 20 nm, although lesser and greater thicknesses can also be employed. The stack of the blocking dielectric layer 52, the memory material layer 54, and the dielectric isolation liner 56 constitutes a memory film 50 that stores memory bits.

The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L includes amorphous silicon or polysilicon. The semiconductor channel material layer 60L can be formed by a conformal deposition method such as low pressure chemical vapor deposition (LPCVD). The thickness of the semiconductor channel material layer 60L can be in a range from 2 nm to 10 nm, although lesser and greater thicknesses can also be employed. A cavity 49′ is formed in the volume of each memory opening 49 that is not filled with the deposited material layers (52, 54, 56, 60L).

Referring to FIG. 25C, in case the cavity 49′ in each memory opening is not completely filled by the semiconductor channel material layer 60L, a dielectric core layer can be deposited in the cavity 49′ to fill any remaining portion of the cavity 49′ within each memory opening. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating. The horizontal portion of the dielectric core layer overlying the second insulating cap layer 270 can be removed, for example, by a recess etch. The recess etch continues until top surfaces of the remaining portions of the dielectric core layer are recessed to a height between the top surface of the second insulating cap layer 270 and the bottom surface of the second insulating cap layer 270. Each remaining portion of the dielectric core layer constitutes a dielectric core 62.

Referring to FIG. 25D, a doped semiconductor material can be deposited in cavities overlying the dielectric cores 62. The doped semiconductor material has a doping of the opposite conductivity type of the doping of the semiconductor channel material layer 60L. Thus, the doped semiconductor material has a doping of the second conductivity type. Portions of the deposited doped semiconductor material, the semiconductor channel material layer 60L, the dielectric isolation liner 56, the memory material layer 54, and the blocking dielectric layer 52 that overlie the horizontal plane including the top surface of the second insulating cap layer 270 can be removed by a planarization process such as a chemical mechanical planarization (CMP) process.

Each remaining portion of the doped semiconductor material having a doping of the second conductivity type constitutes a drain region 63. The drain regions 63 can have a doping of a second conductivity type that is the opposite of the first conductivity type. For example, if the first conductivity type is p-type, the second conductivity type is n-type, and vice versa. The dopant concentration in the drain regions 63 can be in a range from 5.0×10¹⁸/cm³ to 2.0×10²¹/cm³, although lesser and greater dopant concentrations can also be employed. The doped semiconductor material can be, for example, doped polysilicon.

Each remaining portion of the semiconductor channel material layer 60L constitutes a vertical semiconductor channel 60 through which electrical current can flow when a vertical NAND device including the vertical semiconductor channel 60 is turned on. A dielectric isolation liner 56 is surrounded by a memory material layer 54, and laterally surrounds a vertical semiconductor channel 60. Each adjoining set of a blocking dielectric layer 52, a memory material layer 54, and a dielectric isolation liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of backside recesses. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a vertical semiconductor channel 60, a dielectric isolation liner 56, a plurality of memory elements comprises portions of the memory material layer 54, and an optional blocking dielectric layer 52. Each combination of a memory stack structure 55, a dielectric core 62, and a drain region 63 within a memory opening 49 constitutes a memory opening fill structure 58. Each of the memory opening fill structures 58 comprises a respective vertical stack of memory elements (which may be embodied as portions of a memory material layer 54 located at levels of the sacrificial material layers 42) and a respective vertical semiconductor channel 60.

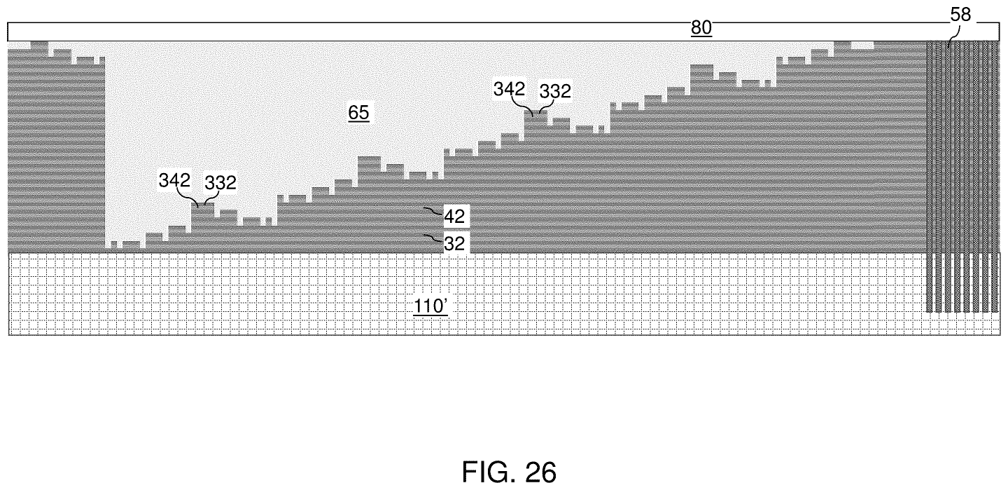

Referring to FIG. 26, a contact-level dielectric layer 80 can be formed over the alternating stack (32, 42) embedding the memory opening fill structures 58 and over the stepped dielectric material portion 65. The contact-level dielectric layer 80 comprises a dielectric material that is different from the material of the sacrificial material layers 42. For example, the contact-level dielectric layer 80 comprises silicon oxide. The thickness of the contact-level dielectric layer 80 may be in a range from 100 nm to 600 nm, although lesser and grater thicknesses may also be employed.

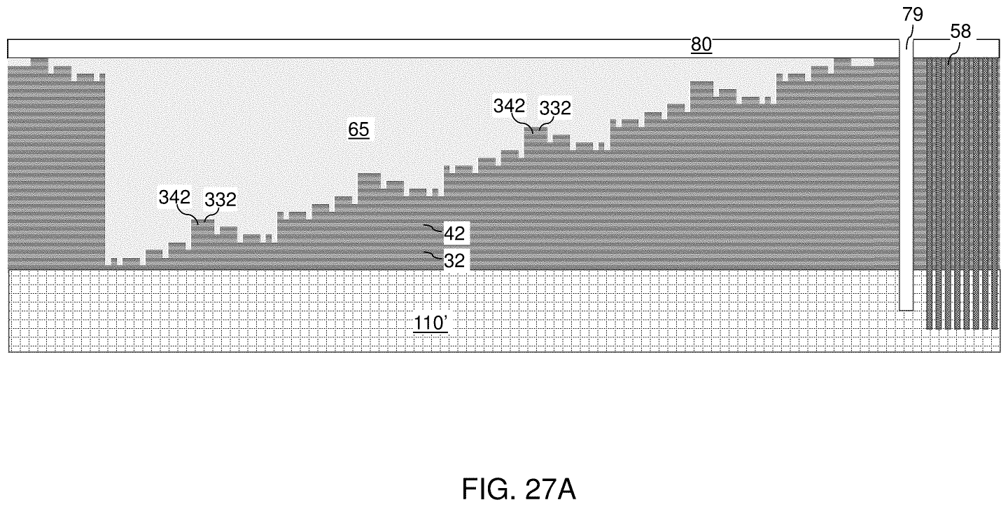

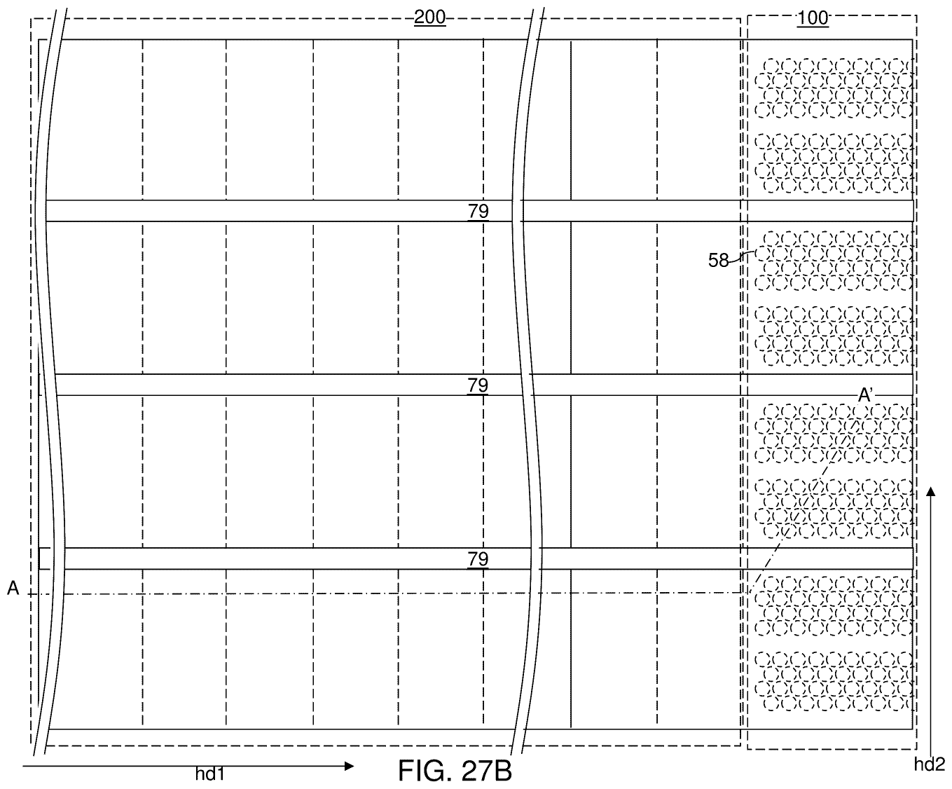

Referring to FIGS. 27A and 27B, a photoresist layer (not shown) can be applied over the contact-level dielectric layer 80, and is lithographically patterned to form openings in areas between clusters of memory opening fill structures 58. The pattern in the photoresist layer can be transferred through the contact-level dielectric layer 80, the alternating stack (32, 42) and the stepped dielectric material portion 65 employing an anisotropic etch to form backside trenches 79, which vertically extend from the top surface of the contact-level dielectric layer 80 into the in-process source-level material layers 110′, and laterally extend through the memory array region 100 and the staircase region 200.

In one embodiment, the backside trenches 79 can laterally extend along a first horizontal direction hd1 and can be laterally spaced apart among one another along a second horizontal direction hd2 that is perpendicular to the first horizontal direction hd1. The memory opening fill structures 58 can be arranged in rows that extend along the first horizontal direction hd1. Optionally, drain-select-level isolation structures (not shown) laterally extending along the first horizontal direction hd1 may be formed. Each backside trench 79 can have a uniform width that is invariant along the lengthwise direction (i.e., along the first horizontal direction hd1).

In one embodiment, the final vertical stacks (332, 342) may be laterally spaced from the backside trenches 79 by remaining portions of the stepped dielectric material portions 65. In this case, the final vertical stacks (332, 342) are not physically exposed to the backside trenches 79. In an alternative embodiment, the final vertical stacks (332, 342) may be physically exposed to the backside trenches. In this case, the backside trenches 79 may cut through end portions of the final vertical stacks (332, 342).

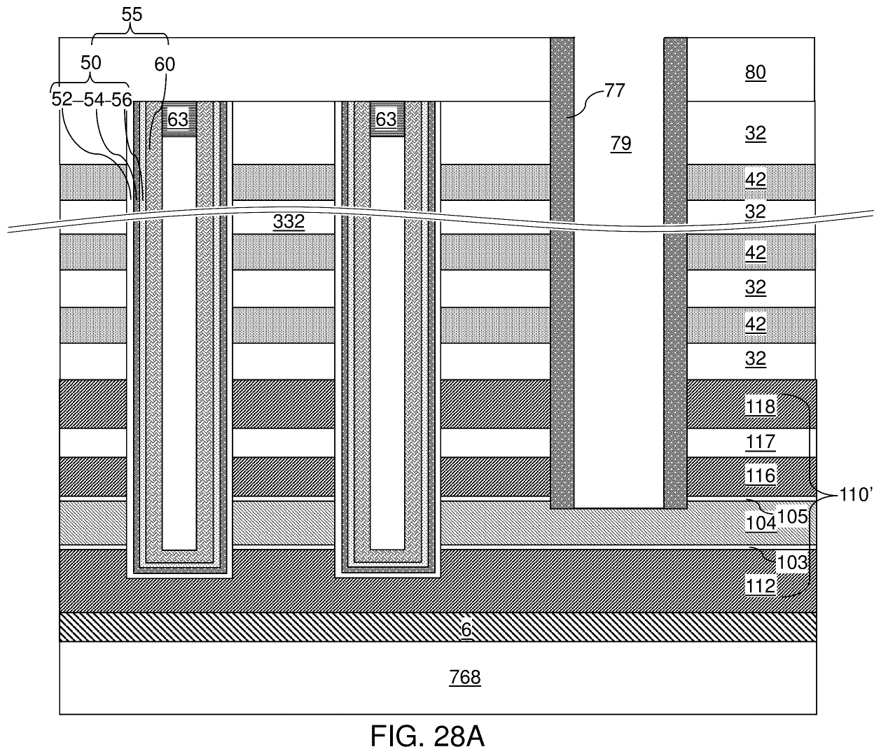

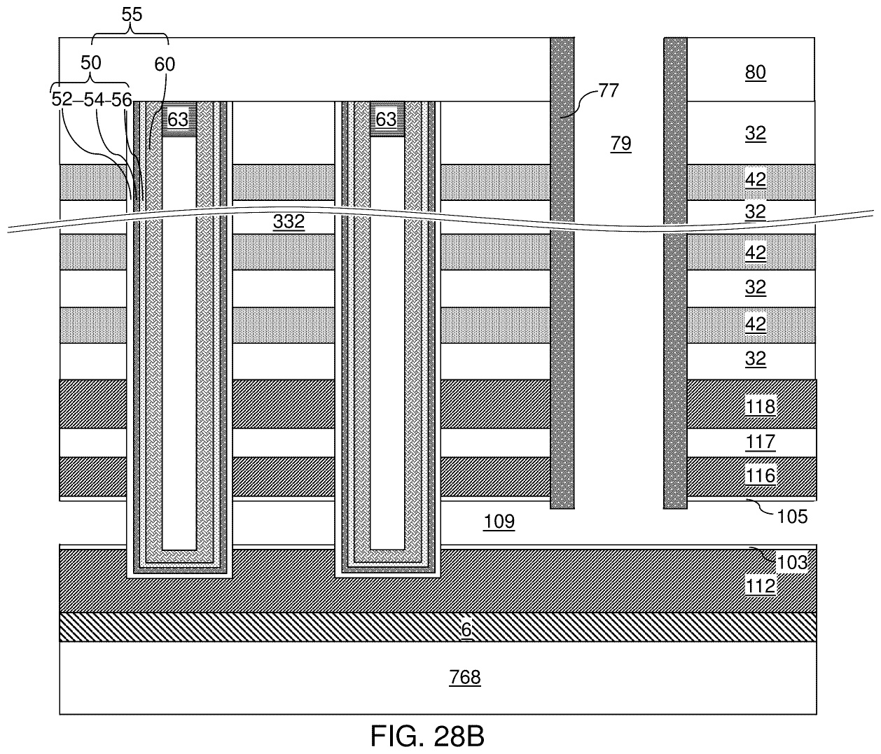

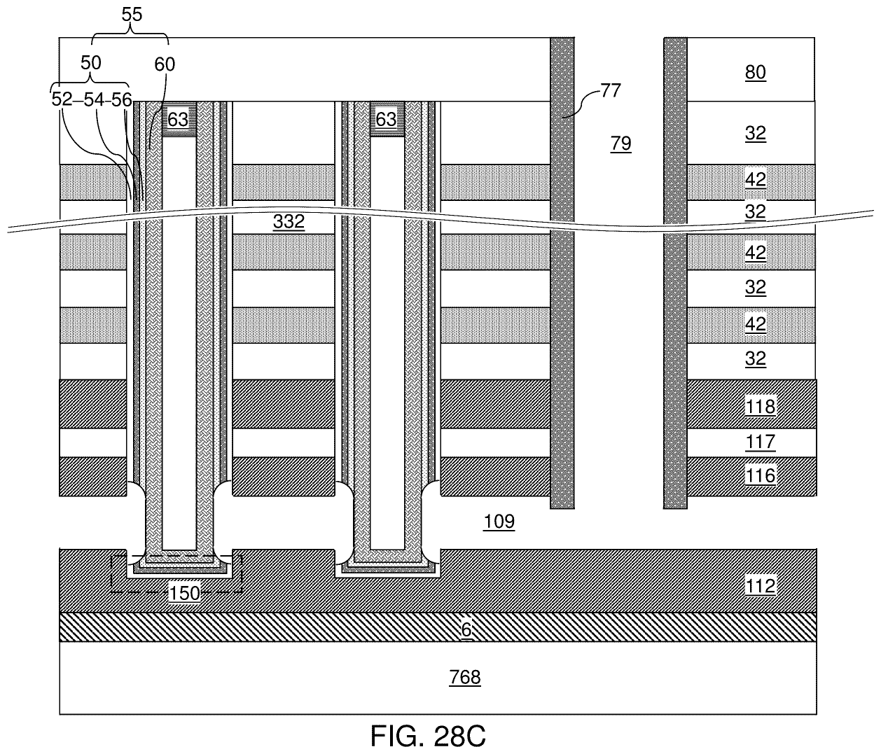

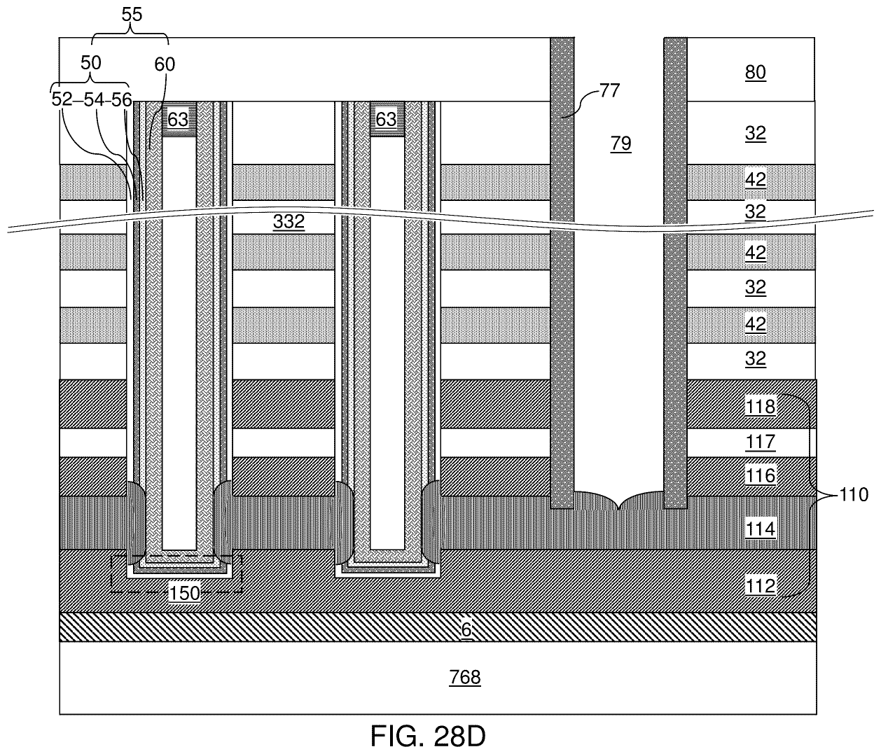

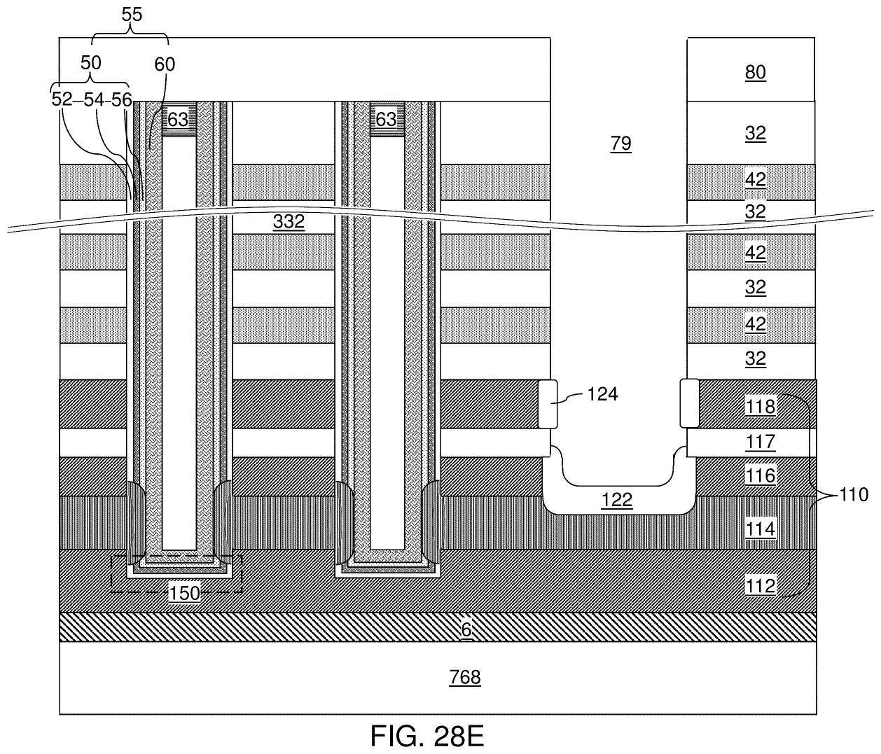

FIGS. 28A-28E illustrate sequential vertical cross-sectional views of a region of the first exemplary structure during formation of source-level material layers 110 according to the first embodiment of the present disclosure.

Referring to FIG. 28A, a backside trench spacer 77 can be formed on sidewalls of each backside trench 79. For example, a conformal spacer material layer can be deposited in the backside trenches 79 and over the contact-level dielectric layer 80, and can be anisotropically etched to form the backside trench spacers 77. The backside trench spacers 77 include a material that is different from the material of the source-level sacrificial layer 104. For example, the backside trench spacers 77 can include silicon oxide, a dielectric metal oxide, or silicon nitride.

Referring to FIG. 28B, an etchant that etches the material of the source-level sacrificial layer 104 selective to the materials of the alternating stack (32, 42), the contact-level dielectric layer 80, the upper dielectric liner layer 105, and the lower dielectric liner layer 103 can be introduced into the backside trenches 79 in an isotropic etch process. For example, if the source-level sacrificial layer 104 includes undoped amorphous silicon or polysilicon, the backside trench spacers 77 include silicon nitride, and the upper and lower dielectric liner layers (105, 103) include silicon oxide, a wet etch process employing hot trimethyl-2 hydroxyethyl ammonium hydroxide (“hot TMY”) or tetramethyl ammonium hydroxide (TMAH) can be employed to remove the source-level sacrificial layer 104 selective to the backside trench spacers 77 and the upper and lower dielectric liner layers (105, 103). Alternatively, if the source-level sacrificial material layer 104 includes silicon nitride, the backside trench spacers 77 include silicon oxide or a dielectric metal oxide, and the upper and lower dielectric liner layers (105, 103) include silicon oxide, a wet etch process employing hot phosphoric acid can be employed to remove the source-level sacrificial layer 104 selective to the backside trench spacers 77 and the upper and lower dielectric liner layers (105, 103). A source cavity 109 is formed in the volume from which the source-level sacrificial layer 104 is removed.

Referring to FIG. 28C, a sequence of isotropic etchants, such as wet etchants, can be applied through the backside trenches 79 and the source cavity 109 to the physically exposed portions of the memory films 50 to sequentially etch the various component layers of the memory films 50 from outside to inside, and to physically expose bottom surfaces and cylindrical side surfaces of the vertical semiconductor channels 60 at the level of the source cavity 109. The upper and lower dielectric liner layers (105, 103) can be collaterally etched during removal of the portions of the memory films 50 located at the level of the source cavity 109. The source cavity 109 can be expanded in volume by removal of the portions of the memory films 50 at the level of the source cavity 109 and the upper and lower dielectric liner layers (105, 103). A top surface of the lower source-level material layer 112 and a bottom surface of the upper source-level material layer 116 can be physically exposed to the source cavity 109. An outer sidewall of each vertical semiconductor channel 60 is physically exposed to the source cavity 109 after removing the physically exposed portions of the memory films 50. A dielectric material stack 150 is formed underneath each physically exposed cylindrical surface of the vertical semiconductor channels 60. Each dielectric material stack 150 is a remaining portion of the memory films 50, and includes the same dielectric material stack as the memory films 50.

Thus, the upper source-level material layer 116 can act as an etch stop during the selective etching of the memory film 50 through the source cavity 109 and can prevent lateral expansion of the source cavity 109. This prevents a short circuit between the source-select-level conductive layer 118 and a source contact layer that is subsequently formed in the source cavity 109 during a subsequent step.

Referring to FIG. 28D, a source contact layer 114 can be formed by a selective deposition process that deposits a doped semiconductor material having a doping of the second conductivity type, which is herein referred to as a third doped semiconductor material. The doped semiconductor material can include amorphous silicon, polysilicon, or a silicon-germanium alloy. The third doped semiconductor material of the source contact layer 114 can grow from physically exposed semiconductor surfaces around the source cavity 109. The average atomic concentration of dopants of the second conductivity type in the source contact layer 114 can be in a range from 5.0×10¹⁹/cm³ to 2.0×10²¹/cm³, although lesser and greater dopant concentrations can also be employed.

The in-process source-level material layers 110′ are replaced with source-level material layers 10. The source-level material layers 110 include a layer stack including, from bottom to top, the lower source-level material layer 112, the source contact layer 114, the upper source-level material layer 116, the source-level insulating layer 117, and the optional source-select-level conductive layer 118. The combination of the lower source-level material layer 112, the source contact layer 114, the upper source-level material layer 116 constitutes a source layer (112, 114, 116). Upon replacement of the source-level sacrificial layer 104 with a source contact layer 114, the in-process source-level material layers 110′ are converted into source-level material layers 110 including a source layer (112, 114, 116).

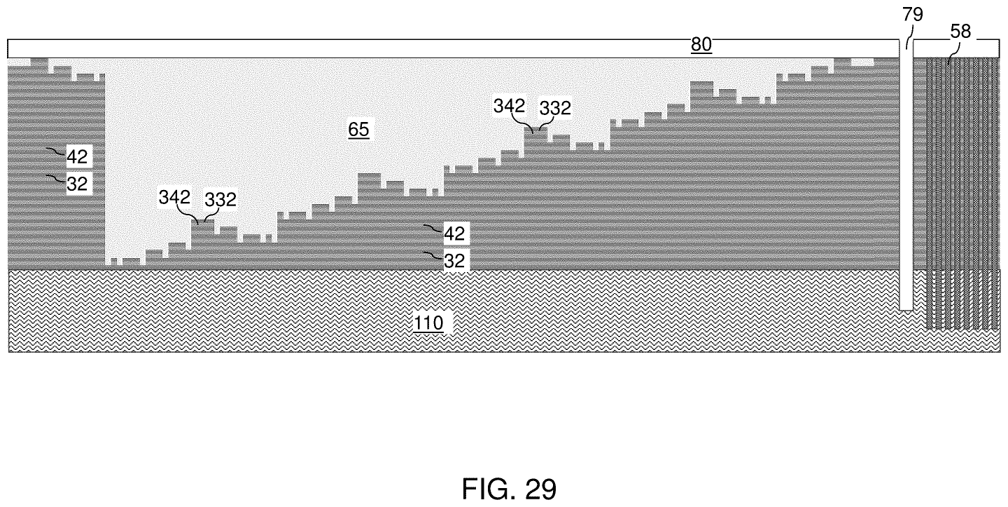

Referring to FIGS. 28E and 29, the backside trench spacers 77 can be removed selective to the semiconductor materials of the source contact layer 114. For example, if the backside trench spacers 77 include silicon nitride, a wet etch process employing hot phosphoric acid can be employed to remove the backside trench spacers 77. If the backside trench spacers 77 include silicon oxide, a wet etch process employing dilute hydrofluoric acid can be employed to remove the backside trench spacers 77. Sidewalls of the alternating stacks (32, 42), the upper source-level material layer 116, the source-level insulating layer 117, and the optional source-select-level conductive layer 118 can be physically exposed after removal of the backside trench spacers 77.

A thermal oxidation process can be performed to convert physically exposed surface portions of various semiconductor materials into semiconductor oxide portions. Specifically, physically exposed surface portions of the source contact layer 114, the upper source-level material layer 116, and the source-select-level conductive layer 118 (if present) are converted into thermal semiconductor oxide material portions. As used herein, a “thermal semiconductor oxide” refers to a material that is formed by thermal oxidation of a semiconductor material. Unlike a semiconductor oxide material formed by chemical vapor deposition, thermal semiconductor oxide materials do not include carbon or hydrogen above a trace level unless the semiconductor material from which the semiconductor oxide material is derived includes carbon prior to a thermal oxidation process.

The thermal oxidation process forms a semiconductor oxide plate 122 at the bottom of each backside trench 79 and semiconductor oxide rails 124 on sidewalls of the source-select-level conductive layer 118. The semiconductor oxide rails 124 are not illustrated in FIG. 29 for clarity. The semiconductor oxide plate 122 includes various thermal semiconductor oxide material portions formed by thermal conversion of surface portions of the source contact layer 114 and the upper source-level material layer 116.

The layer stack including the lower source-level material layer 112, the source contact layer 114, and the upper source-level material layer 116 constitutes a source layer (112, 114, 116), which is a buried source layer that functions as a common source region that is connected each of the vertical semiconductor channels 60 and has a doping of the second conductivity type. The average dopant concentration in the buried source layer (112, 114, 116) can be in a range from 5.0×10¹⁹/cm³ to 2.0×10²¹/cm³, although lesser and greater dopant concentrations can also be employed.

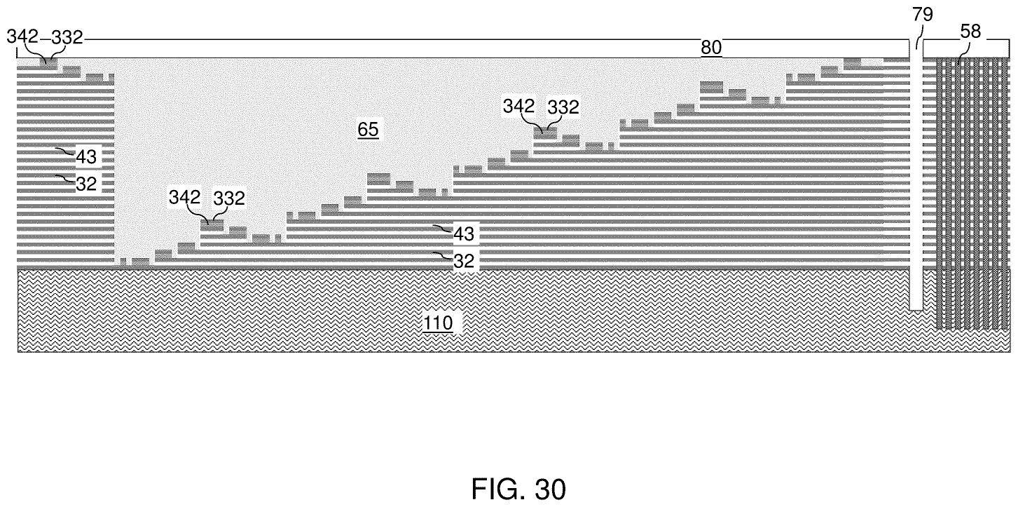

Referring to FIG. 30, an etchant that selectively etches the materials of the sacrificial material layers 42 with respect to the materials of the insulating layers 32, the retro-stepped dielectric material portions 65, and the material of the outermost layer of the memory films 50 can be introduced into the backside trenches 79, for example, employing an isotropic etch process. For example, the sacrificial material layers 42 can include silicon nitride, the materials of the insulating layers 32, the contact-level dielectric layer 80, the retro-stepped dielectric material portions 65, and the material of the outermost layer of the memory films 50 can include silicon oxide materials. Backside recesses 143 are formed in volumes from which the sacrificial material layers 142 are removed.

The isotropic etch process can be a wet etch process employing a wet etch solution, or can be a gas phase (dry) etch process in which the etchant is introduced in a vapor phase into the backside trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. Each of the backside recesses 43 can be a laterally extending cavity having a lateral dimension that is greater than the vertical extent of the cavity. In other words, the lateral dimension of each of the backside recesses 43 can be greater than the height of the respective backside recess 43. A plurality of first backside recesses 143 can be formed in the volumes from which the sacrificial material layers 142 is removed. Each of the backside recesses 43 can extend substantially parallel to the top surface of the substrate 8.

In the first embodiment, the vertical stacks of final insulating plates 332 and final dielectric material plates 342 can be laterally spaced apart from the backside trenches 79. In this case, the final dielectric material plates 342 are not removed by the isotropic etch process, and the vertical stacks of final insulating plates 332 and final dielectric material plates 342 are not modified during formation of the backside recesses 43.

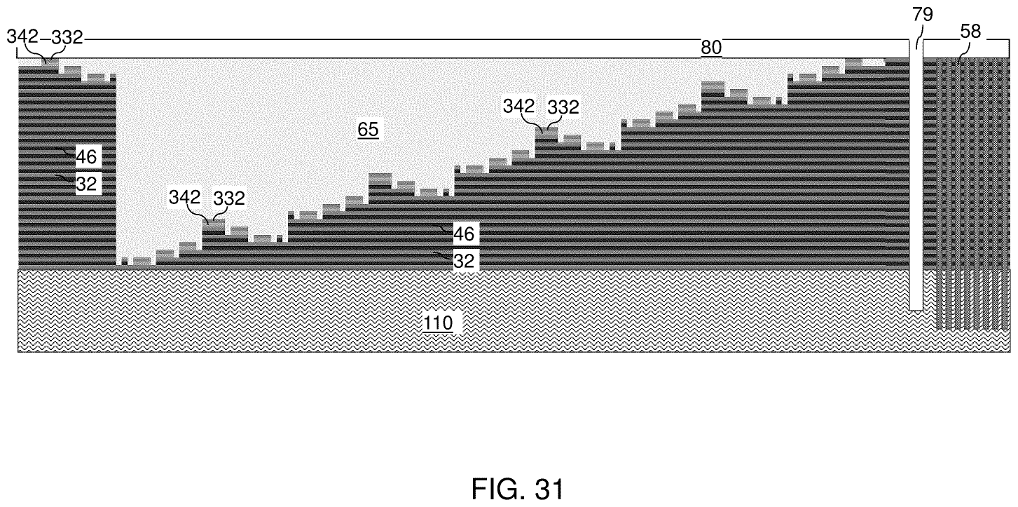

Referring to FIG. 31, a backside blocking dielectric layer (not shown) can be optionally deposited in the backside recesses and the backside trenches 79 and over the contact-level dielectric layer 80. At least one conductive material can be deposited in the plurality of backside recesses 43, on the sidewalls of the backside trench 79, and over the contact-level dielectric layer 80. The at least one conductive material can include at least one metallic material, i.e., an electrically conductive material that includes at least one metallic element.

The metallic material can be deposited by a conformal deposition method, which can be, for example, chemical vapor deposition (CVD), atomic layer deposition (ALD), electroless plating, electroplating, or a combination thereof. The metallic material can be an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof. Non-limiting exemplary metallic materials that can be deposited in the backside recesses include tungsten, tungsten nitride, titanium, titanium nitride, tantalum, tantalum nitride, cobalt, and ruthenium. In one embodiment, the metallic material can comprise a metal such as tungsten and/or metal nitride. In one embodiment, the metallic material for filling the backside recesses can be a combination of titanium nitride layer and a tungsten fill material. In one embodiment, the metallic material can be deposited by chemical vapor deposition or atomic layer deposition.

An etch back process can be performed to remove the at least one conductive material from inside the backside trenches 79 and from above the contact-level dielectric layer 80. The etch back process may comprise an isotropic etch process or an anisotropic etch process. Remaining portions of the at least one conductive material filling the backside recesses 43 comprise electrically conductive layers 46.

Each of the memory opening fill structures 58 (which contains a respective memory stack structures 55) comprises a vertical stack of memory elements located at each level of the electrically conductive layers 46. A subset of the electrically conductive layers 46 can comprise word lines for the memory elements. The semiconductor devices in the underlying peripheral device region 700 can comprise word line switch devices configured to control a bias voltage to respective word lines. The memory-level assembly includes all structures located above the topmost surface of the lower-level metal interconnect structures 780, and is located over, and is vertically spaced from, the substrate semiconductor layer 9.

Alternating stacks (32, 46) of insulating layers 32 and electrically conductive layers 46 are formed, which are laterally spaced apart from each other by the backside trenches 79 along the second horizontal direction hd1. In one embodiment, the device includes the source layer (112, 114, 116) which comprises: a lower source-level material layer 112 comprising a first doped semiconductor material; an upper source-level material layer 116 comprising a second doped semiconductor material; and a source contact layer 114 comprising a third doped semiconductor material and located between the upper source-level material layer 116 and the lower source-level material layer 112. In one embodiment, each of the vertical semiconductor channels 60 is in contact with the source contact layer 114. In one embodiment, each of the memory opening fill structures 58 comprises a respective memory film 50 that laterally surrounds the respective vertical semiconductor channel 60, has a respective annular concave bottom surface contacting the source contact layer 114, and has a respective cylindrical outer surface contacting the upper source-level material layer 116 and each insulating layer within a respective one of the alternating stacks (32, 46).

Generally, at least one electrically conductive material can be deposited in the backside recesses 43 by performing a deposition process that employs the backside trenches 79 as conduits for a precursor gas for the electrically conductive material. Deposited portions of the electrically conductive material comprise the electrically conductive layers 46. Remaining portions of the sacrificial material layers 42 that underlie the final vertical stacks (332, 342) after formation of the backside trenches 79 are replaced with the electrically conductive layers 46.

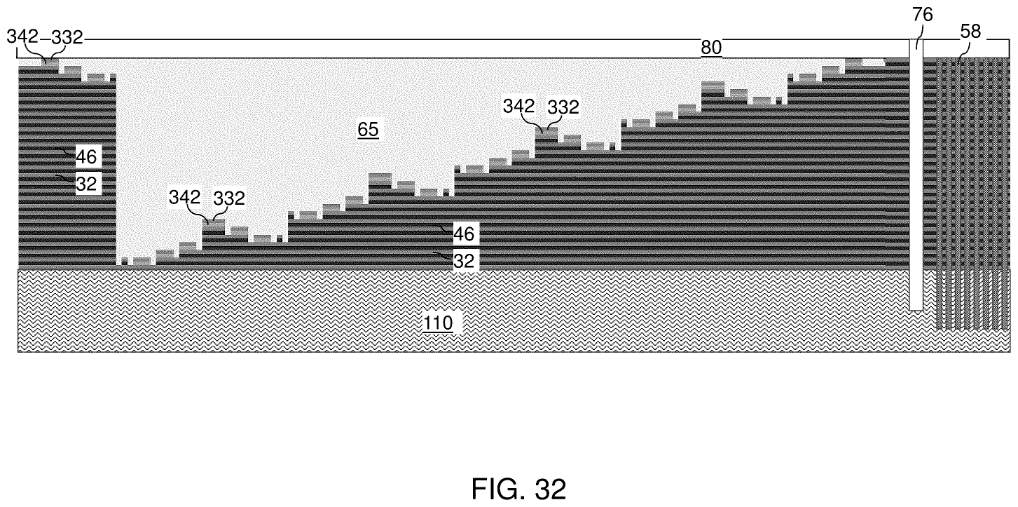

Referring to FIG. 32, a dielectric backside trench fill material such as silicon oxide can be deposited at least at a peripheral portion of each of the backside trenches 79. In one embodiment, the entirety of each backside trench 79 may be filled with the dielectric backside trench fill material. In another embodiment, the dielectric backside trench fill material does not completely fill the backside trenches 79. In this case, an anisotropic etch process may be performed to remove horizontally-extending portions of the dielectric backside trench fill material and to provide a backside insulating spacer (not shown) at a periphery of each backside trench 79, and a backside contact via structure may be formed within each cavity that is laterally surrounded by a respective backside insulating spacer. Generally, a backside trench fill structure 76 can be formed in each backside trench 79 such that each alternating stack of insulating layers 32 and electrically conductive layers 46 contacts a dielectric sidewall of a respective backside trench fill structure 76. In the first embodiment, the vertical stacks of final insulating plates 332 and final dielectric material plates 342 are laterally spaced from the backside trench fill structures 76.

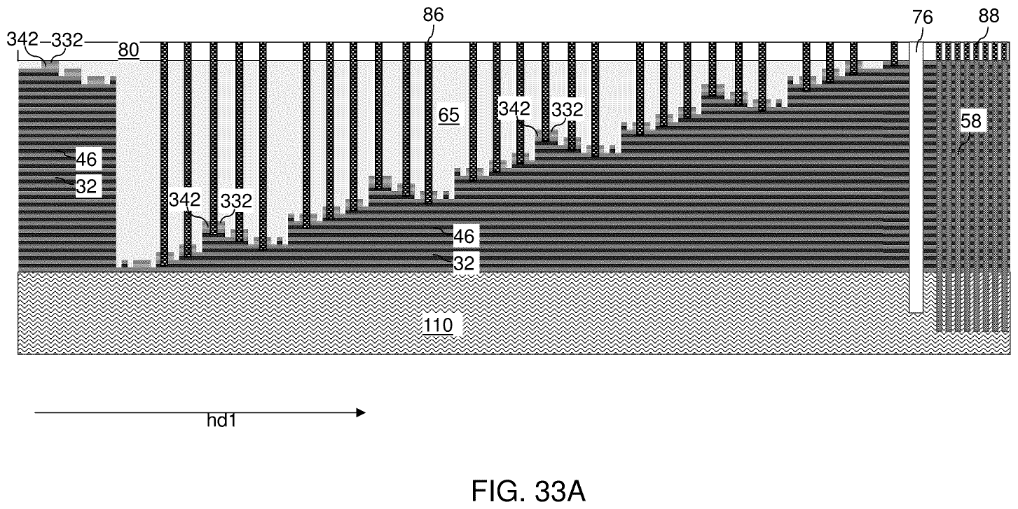

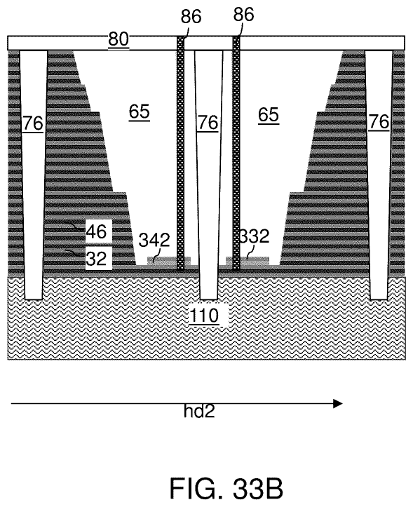

Referring to FIGS. 33A and 33B, a photoresist layer (not shown) can be applied over the contact-level dielectric layer 80, and can be lithographically patterned to form openings therethrough. In one embodiment, the openings in the photoresist layer may be formed within the areas of vertical stacks of a respective final insulating plate 332 and a respective final dielectric material plate 342 in a plan view (i.e., a view along a vertical direction).

An anisotropic etch process can be performed to transfer the pattern of the openings in the photoresist layer through the contact-level dielectric layer 80, the stepped dielectric material portion 65, and the vertical stacks of a respective final insulating plate 332 and a respective final dielectric material plate 342. Layer contact via cavities are formed underneath the openings in the photoresist layer. Generally, the layer contact via cavities can be formed by applying a patterned etch mask layer (such as a photoresist layer) including discrete openings therethrough over the stepped dielectric material portion 65, and by performing an anisotropic etch process that transfers the pattern of the discrete openings through the stepped dielectric material portion 65 and the vertical stacks of a respective final insulating plate 332 and a respective final dielectric material plate 342.

According to an aspect of the present disclosure, the anisotropic etch process comprises a first etch step that etches the material of the stepped dielectric material portion 65 selective to at least one material within the final vertical stacks (332, 342). In one embodiment, a final insulating plate 332 may overlie a final dielectric material plate 342 within each vertical stack of a final insulating plate 332 and a final dielectric material plate 342. In one embodiment, the first etch step may etch the material of the stepped dielectric material portion 65 and the final insulating plate 332 selective to the material of the final dielectric material plates 342, which act as etch stop plates.

In one embodiment, the anisotropic etch process includes a second etch step that etches a material of the final dielectric material plates 342 selective to the material of the insulating layers 32. In one embodiment, the anisotropic etch process includes a third etch step that etches the material of the insulating layers 32 selective to the material of the electrically conductive layers 46. A top surface of an electrically conductive layer 46 can be physically exposed at the bottom of each layer contact via cavity. The photoresist layer can be subsequently removed, for example, by ashing.

An additional photoresist layer (not shown) can be applied over the contact-level dielectric layer 80, and can be lithographically patterned to form an array of openings over the array of memory opening fill structures 58. An anisotropic etch process can be performed to form drain contact via cavities over the array of memory opening fill structures 58. The additional photoresist layer can be subsequently removed, for example, by ashing. Alternatively, the drain contact via cavities and the contact via cavities may be formed during the same etching step using a single photoresist layer.

At least one conductive material can be deposited in the layer contact via cavities and in the drain contact via cavities. Excess portions of the at least one conductive material can be removed from above the horizontal plane including the top surface of the contact-level dielectric layer 80. Each portion of the at least one conductive material filling the layer contact via cavities comprise layer contact via structures 86. Each portion of the at least one conductive material filling the layer contact via cavities comprise drain contact via structures 88. Each layer contact via structure 86 contacts a top surface of a respective electrically conductive layer 46. Each drain contact via structure 88 contacts a top surface of a respective drain region 63. Subsequently, bit lines (not shown) are formed in electrical contact with the drain contact via structures 88 and various interconnects (not shown) are formed to provide an electrical connection between the electrically conductive layers 46 (e.g., word lines and select gate electrodes) and word line switching circuits which may comprise some of the semiconductor devices 710.

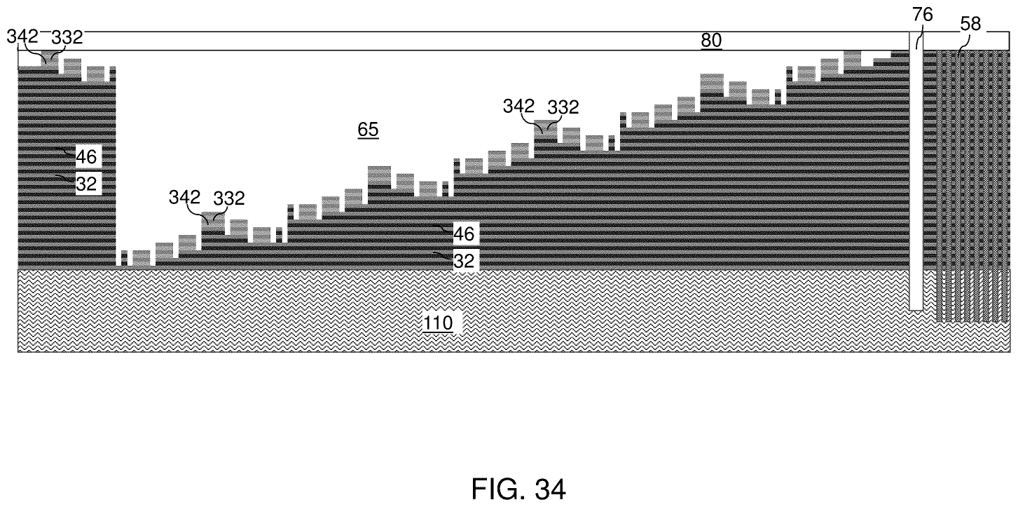

Referring to FIG. 34, a second exemplary structure according to a second embodiment of the present disclosure is illustrated after formation of backside trench fill structures 76. The second exemplary structure can be derived from the first exemplary structure illustrated in FIG. 4 by transferring the pattern in the first patterned photoresist layer 671 through two underlying insulating layers 32 and two underlying sacrificial material layers 42 in a subsequent anisotropic etch step described with reference to FIG. 5. In other words, the topmost sacrificial material layer 42, the topmost insulating layer 32, the second-from-the-top sacrificial material layer 42, and the second-from-the-top insulating layer 32 can be patterned by performing an anisotropic etch process employing the first patterned photoresist layer 671 illustrated in FIG. 4 as an etch mask.

Each patterned portion of the sacrificial material layers 42 comprises an initial dielectric material plate 142, and each patterned portion of the insulating material layers 32 comprises an initial insulating plate 132. Vertical stacks of two initial insulating plates 132 and two dielectric material plates 142 can be formed.

Subsequently, the processing steps described with reference to FIGS. 5-22 can be performed. The vertical stacks of two initial insulating plates 132 and two discrete material plates 142 are converted into vertical stacks of two intermediate insulating plates 232 and two intermediate discrete material plates 242 at the processing steps described with reference to FIG. 7, and are subsequently converted into vertical stacks of two final insulating plates 332 and two final discrete material plates (e.g., final dielectric material plates) 342 at the processing steps described with reference to FIG. 21.

Subsequently, the processing steps described with reference to FIGS. 23, 24, 25A-25D, 26, 27A and 27D, 28A-28E, 29, 30, 31, and 32 can be performed to provide the second exemplary structure illustrated in FIG. 34.

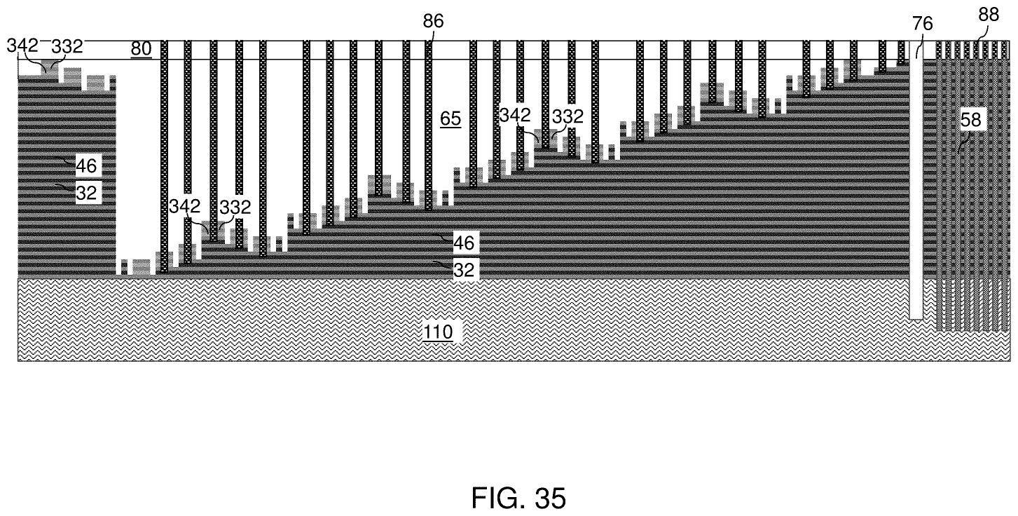

Referring to FIG. 35, the processing steps described with reference to FIG. 33 can be performed with a modification in the anisotropic etch process. Specifically, the anisotropic etch process employed to etch the layer contact via cavities may comprise a first etch step that etches the material of the stepped dielectric material portion 65 selective to at least one material within the final vertical stacks (332, 342). In one embodiment, a final insulating plate 332 may be the topmost plate within each vertical stack of two final insulating plates 332 and two final dielectric material plates 342. In one embodiment, the first etch step may etch the material of the stepped dielectric material portion 65 and the material of the final insulating plates 332 selective to the material of the final dielectric material plates 342, which act as etch stop plates.

In one embodiment, the anisotropic etch process may comprise an alternating sequence of a second etch step, a third etch step, an additional second etch step, and an additional third etch step that follows the first etch step. Each second etch step etches a material of the final dielectric material plates 342 selective to a material of the final insulating plates 332 (which is the material of the insulating layers 32). Each third etch step etches the material of the final insulating plates 332 selective to the material of the final dielectric material plates 342 or selective to a material of the electrically conductive layers 46. In one embodiment, the third etch step that is performed prior to the additional second etch step may etch the material of the final insulating plates 332 selective to the material of the final dielectric material plates 342, and the additional third etch step may etch the material of the final dielectric material plates 342 selective to the material of the electrically conductive layers 46. The alternating sequence of the second etch step, the third etch step, the additional second etch step, and the additional third etch step can sequentially etch through an upper final dielectric material plate 342, an upper final insulating plate 332, a lower final dielectric material plate 342, and a lower final insulating plate 332 so that a top surface of an electrically conductive layer 46 is physically exposed at the bottom of each layer contact via cavity.

Subsequently, at least one conductive material can be deposited in each of the layer contact via cavities and drain contact via cavities to form layer contact via structures 86 and drain contact via structures 88.

Generally, each final vertical stack within the final vertical stacks (332, 342) comprises a vertically alternating sequence of a respective plurality of final insulating plates 332 and a respective plurality of final dielectric material plates 342. For example, in one embodiment, each final vertical stack within the final vertical stacks (332, 342) comprises a vertically alternating sequence of a respective three final insulating plates 332 and a respective three final dielectric material plates 342.

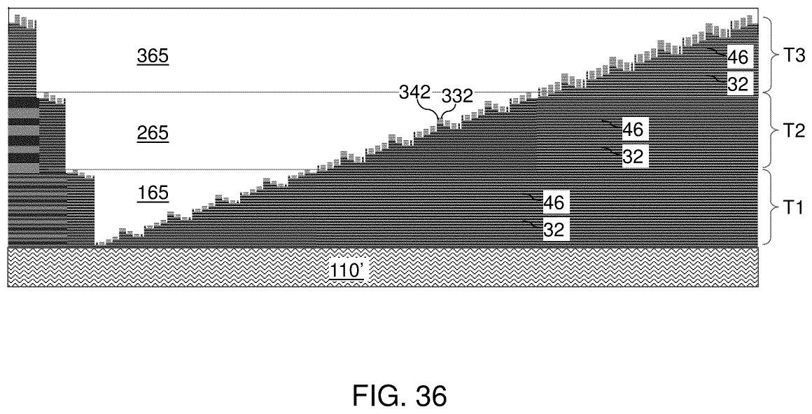

Referring to FIG. 36, a third exemplary structure according to a third embodiment of the present disclosure is illustrated. The third exemplary structure is a multi-tier structure in which multiple tiers (T1, T2, T3) of a respective alternating stack of insulating layers 32 and sacrificial material layers 42 and a respective stepped dielectric material portion (165, 265, 365) are sequentially formed over the in-process source-level material layers 110′. Each tier (T1, T2, T3) comprises a respective set of vertical stacks of final insulating plates 332 and final dielectric material plates 342. A contact-level dielectric material layer 80 can be formed over the top tier, and the processing steps described with reference to FIGS. 24-33B can be subsequently performed.

In the third embodiment, different final vertical stacks (332, 342) contain a different number of final insulating plates 332 and final dielectric material plates 342. For example, the final vertical stacks (332, 324) in the first (i.e., lowest) tier T1 include one final insulating plate 332 and one final dielectric material plate 342. The final vertical stacks (332, 324) in the second (i.e., middle) tier T2 include two final insulating plates 332 and two final dielectric material plates 342. The final vertical stacks (332, 324) in the third (i.e., highest) tier T3 include three final insulating plates 332 and three final dielectric material plates 342. Other different numbers of final insulating plates 332 and final dielectric material plates 342 may be included in different tiers.

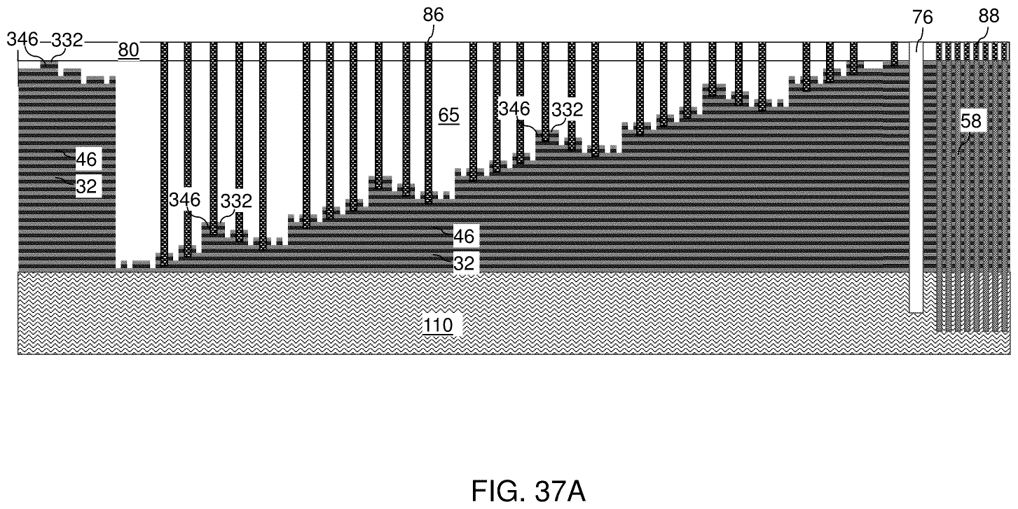

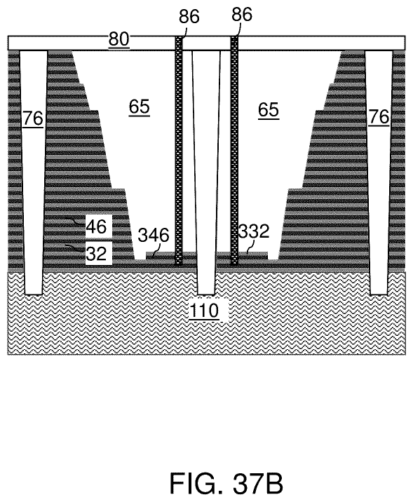

Referring to FIGS. 37A and 37B, a fourth exemplary structure according to a fourth embodiment of the present disclosure is illustrated. The fourth exemplary structure can be derived from any of the previously described exemplary structures by patterning the vertical stacks of final insulating plates 332 and final dielectric material plates 342 at the processing steps corresponding to the processing steps described with reference to FIG. 22 such that each vertical stack of a respective set of at least one final insulating plate 332 and a respective set of at least one final dielectric material plate 342 has a partial areal overlap with a respective backside trench 79 to be subsequently formed. Thus, upon formation of the backside trenches 79, the sidewalls of the vertical stacks of at least one final insulating plate 332 and at least one dielectric material plate 342 are physically exposed to the backside trenches 79.

Since the dielectric material plates 342 comprise the same material as the sacrificial material layers 42, each dielectric material plate 342 is removed during the isotropic etch process that removes the sacrificial material layers 42 to form the backside recesses 43. Lateral recesses are formed in each volume from which the dielectric material plates 342 are removed during the isotropic etch process that forms the backside recesses 43. The at least one conductive material that is deposited in the backside recesses 43 during formation of the electrically conductive layers 46 is also deposited in the lateral recesses. Electrically conductive material plates 346 are formed in the lateral recesses by deposition of the at least one conductive material during formation of the electrically conductive layers 46. The electrically conductive material plates 346 comprise the same material as the electrically conductive layers 46. Vertical stacks of at least one insulating plate 332 and at least one electrically conductive material plate 346 replaces vertical stacks of at least one insulating plate 332 and at least one dielectric material plate 342. In one embodiment, the electrically conductive layers 46 and the electrically conductive material plates 346 comprise at least one metallic material, such as a combination of a conductive metallic nitride liner and a metallic fill material (such as W, Ti, Ta, Mo, Co, Ru, Cu, etc.).

In the fourth exemplary structure, the final dielectric material plates 342 are replaced with electrically conductive material plates 346 concurrently with replacement of the remaining portions of the sacrificial material layers 42 that underlie the final vertical stacks (332, 342) with the electrically conductive layers 46.

Layer contact via cavities by applying a patterned etch mask layer including discrete openings therethrough over the dielectric material portion 65, and by performing an anisotropic etch process having a modified set of etch steps relative to the anisotropic etch processes employed to form the first, second, and third exemplary structures. The anisotropic etch process employed to form the layer contact via cavities in the fourth exemplary structure may comprise a first etch step that etches the material of the stepped dielectric material portion 65 selective to the material of the electrically conductive material plates 346. Further, the anisotropic etch process employed to form the layer contact via cavities in the fourth exemplary structure may comprise least one second etch step that etches the material of the electrically conductive material plates 346 selective to a material of the final insulating plates 332 (which is the same as the material of the insulating layers 32). In one embodiment, the anisotropic etch process employed to form the layer contact via cavities in the fourth exemplary structure may comprise at least one third etch step that etches the material of the final insulating plates 332 selective to the material of the electrically conductive material plates 346 and selective to a material of the electrically conductive layers 46.

In the fourth exemplary structure, all sidewall surfaces of the electrically conductive material plates 346 may be in contact with a material of a respective dielectric material portion 65 or in contact with a dielectric backside trench fill material of a respective backside trench fill structure 76.

Generally, the patterns in the various patterned photoresist material layers (671, 672, 673, 674, 675, 676) can be selected to provide a set of vertical stacks of final insulating plates 332 and final dielectric material plates 342 (or final electrically conductive material plates 346) in a compact layout while ensuring sufficient overlay distance between adjacent edges of patterned photoresist material layers (671, 672, 673, 674, 675, 676).

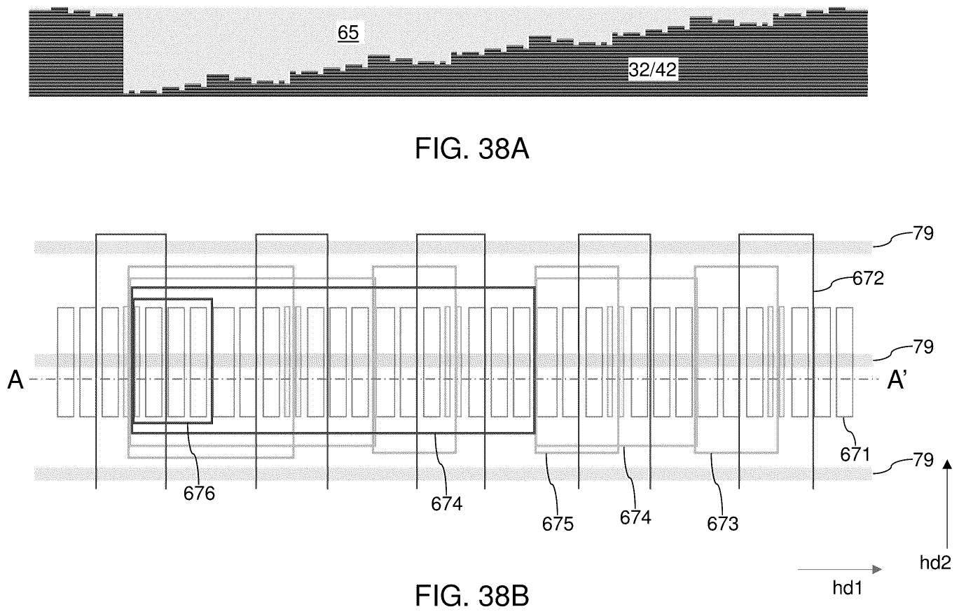

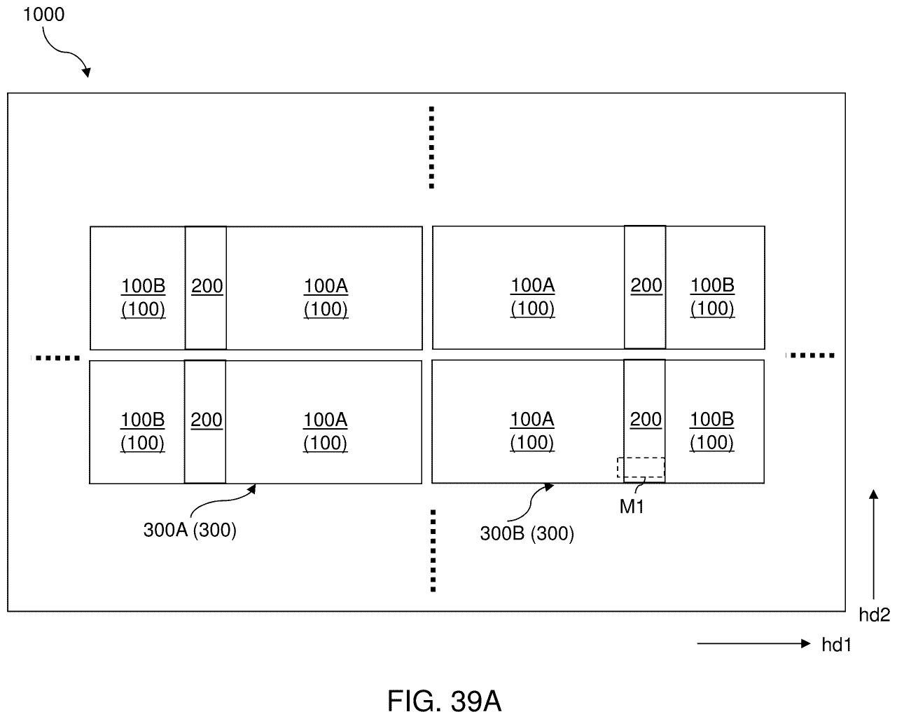

Referring to FIGS. 38A and 38B, an exemplary set of layouts for the various patterned photoresist material layers (671, 672, 673, 674, 675, 676) and for the backside trenches 79 is illustrated. An area of a backside trench 79 overlaps with the patterns of the vertical stacks of final insulating plates 332 and final dielectric material plates 342 in the exemplary set of layouts illustrated in FIGS. 38A and 38B. Thus, the exemplary set of layouts illustrated in FIGS. 38A and 38B can be employed to form the fourth exemplary structure.

The exemplary set of layouts illustrated in FIGS. 38A and 38B may be modified such that the patterns of the vertical stacks of final insulating plates 332 and final dielectric material plates 342 do not overlap with backside trenches 79. Such a set of layouts can be employed to form structures such as the first, second, and/or third exemplary structures.

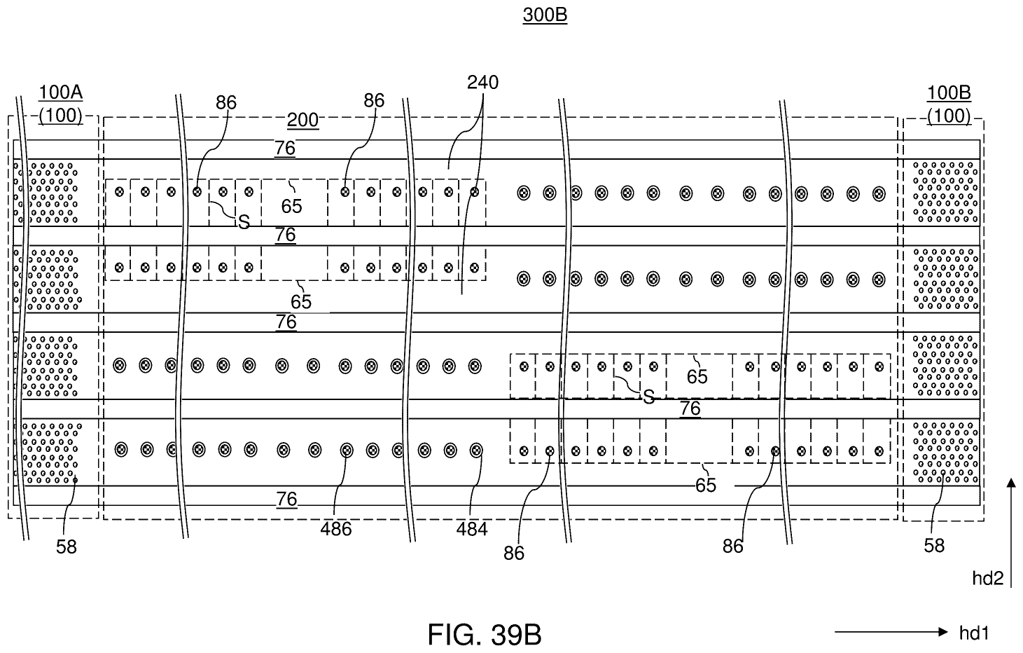

Referring to FIGS. 39A and 39B a first exemplary semiconductor die 1000 according to various embodiments of the present disclosure is illustrated. The first exemplary semiconductor die 1000 includes multiple three-dimensional memory array regions 100 and multiple staircase regions 200 described with respect to first, second, third and/or fourth embodiments above. The first exemplary semiconductor die 1000 can include multiple planes 300 (e.g., 300A, 300B), each of which includes two memory array regions 100, such as a first memory array region 100A and a second memory array region 100B that are laterally spaced apart by a respective staircase region 200. Generally, a semiconductor die 1000 may include a single plane 300 or multiple planes. The total number of planes in the semiconductor die 1000 may be selected based on performance requirements on the semiconductor die 1000. A pair of memory array regions 100 in a plane 300 may be laterally spaced apart along a first horizontal direction hd1 (which may be the word line direction). A second horizontal direction hd2 (which may be the bit line direction) can be perpendicular to the first horizontal direction hd1.

For each area within which a continuous alternating stack (32, 46) continuously laterally extends, first memory stack structures 58 can be located within a respective first memory array region 100A and second memory stack 58 structures can be located within a respective second memory array region 100B. The second memory array region 100B can be connected to the first memory array region 100A through a respective staircase region 200, in which the stepped dielectric material portion 65 is located. Contact via structures 86 vertically extend through the stepped dielectric material portion 65 contact a respective one of the electrically conductive layers 46.

At least a portion of the electrically conductive layers 46 continuously extend from the first memory array region 100A to the second memory array region 100B through a strip-shaped connection region (e.g., a “bridge” region) 240 within a staircase region 200 located between a trench fill structure 76 and a stepped dielectric material portion 65. The staircase region 200 includes strips of the insulating layers 132, and the electrically conductive layers 46 located between each laterally neighboring pair of trench fill structures 76. The portions of the strips in the respective strip-shaped connection (“bridge”) regions 240 of the staircase regions 200 located adjacent to the respective stepped dielectric material portion 65 have a narrower width along the second horizontal direction hd2 than portions of the alternating stacks (32, 46) located in the memory array regions 100 (e.g., 100A and 100B), and portions of the strips located in the remaining portions of the staircase regions 200 outside of the respective strip-shaped connection (“bridge”) regions 240. Each layer within the alternating stack (32, 46) comprises a respective strip portion located within the staircase region 200 and laterally extending continuously from the first memory array region 100A to the second memory array region 100B. Thus, each strip of the insulating layers 32 and the electrically conductive layers 46 can continuously extend from the first memory array region 100A to the second memory array region 100B.

Laterally-isolated vertical interconnection structures (484, 486) can be formed through the staircase region 200. Each laterally-isolated vertical interconnection structure (484, 486) can include a through-memory-level conductive via structure 486 and a tubular insulating spacer 484 that laterally surrounds the conductive via structure 486. Each through-memory-level conductive via structure 486 can contact a lower-level metal interconnect structure 780 located in the lower-level dielectric material layers 760, as shown in FIG. 1A.

According to various embodiments of the present disclosure, a semiconductor structure comprises: an alternating stack of insulating layers 32 and electrically conductive layers 46, wherein the alternating stack (32, 46) comprises stepped surfaces “S”; vertical stacks of at least one insulating plate 332 and at least one spacer material plate (342 or 346), wherein each of the vertical stacks is located on a respective horizontal surface segment of the stepped surfaces; a dielectric material portion 65 having a stepped bottom surface and contacting each of the vertical stacks; and layer contact via structures 86 vertically extending through the dielectric material portion 65 and a respective vertical stack of the vertical stacks and contacting a respective electrically conductive layer 46 of the electrically conductive layers.

In one embodiment, the semiconductor structure comprises a backside trench fill structure 76 comprising a dielectric backside trench fill material at least in a peripheral portion backside trench fill structure 76.

In the first through third embodiments, the spacer material plates 342 comprise a dielectric material having a different material composition than the insulating plates 332 and the insulating layers 32. each sidewall of the insulating plates 332 and the spacer material plates 342 is laterally offset from the dielectric backside trench fill material of the backside trench fill structure 76.

In the fourth embodiment, the spacer material plates 346 and the electrically conductive layers 46 comprise a same electrically conductive material. Each sidewall of the insulating plates 332 and the spacer material plates 346 is in direct contact with the dielectric backside trench fill material of the backside trench fill structure 76.

In the second embodiment, each of the vertical stacks comprises a vertically alternating sequence of a respective plurality of insulating plates 332 and a respective plurality of spacer material plates (342 or 346).

In the third embodiment, a first portion of the alternating stack (32, 46) of insulating layers and electrically conductive layers comprises a first tier T1; a second portion of the alternating stack (32, 46) of insulating layers and electrically conductive layers comprises a second tier T1 located over the first tier; and each of the vertical stacks in the first tier comprises a different number of the insulating plates 332 and the spacer material plates (342 or 346) than each of the vertical stacks in the second tier.

The various embodiments of the present disclosure can be employed to form layer contact via structures 86 while reducing or preventing overetch during formation of layer contact via cavities. The vertical stacks of insulating plates 332 and spacer material plates (342 or 346) can be employed as multiple etch stop structures during the various steps of the anisotropic etch process that forms the layer contact via cavities. Thus, reliable electrical contact can be provided between the layer contact via structures 86 and the electrically conductive layers 46 employing the vertical stacks of insulating plates 332 and spacer material plates (342 or 346). Furthermore, by using discrete plates rather than continuous etch stop layers which extend over plural steps, the undesirable etch stop material (e.g., silicon nitride) residue of sidewalls of the cavity filled by the stepped dielectric material portion 65 is reduced or eliminated. This reduces or eliminates open circuits between the electrically conductive layers 46 and the respective layer contact via structures 86, as well as reduces or eliminates short circuits between vertically adjacent electrically conductive layers 46. This also improves the focus during lithographic patterning on different stepped surfaces since the discrete plate patterning is carried out before the stepped surface formation. Finally, since a continuous etch stop layer is not deposited into the cavity, this reduces non-uniformity of the etch stop material, which reduces or eliminates undesirable penetration of the electrically conductive layers 46 by the layer contact via cavities.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where the third embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A method of forming a semiconductor structure, comprising:
forming an alternating stack of insulating layers and sacrificial material layers over a substrate;
forming a first patterned photoresist layer over the alternating stack, wherein the first patterned photoresist layer comprises a set of discrete photoresist material portions that are laterally spaced apart along a first horizontal direction;
forming initial vertical stacks of at least one initial insulating plate and at least one initial dielectric material plate by transferring a pattern in the first patterned photoresist layer through at least one insulating layer within the insulating layers and at least one sacrificial material layer within the sacrificial material layers;
performing a plurality of pattern transfer process sequences, wherein each of the plurality of pattern transfer process sequences comprises a respective patterned photoresist layer formation step that forms a respective patterned photoresist layer, a respective anisotropic etch process step that transfers a pattern in the respective patterned photoresist layer through at least one underlying insulating layer of the insulating layers and at least one sacrificial material layer of the sacrificial material layers, and a respective photoresist removal step that removes the respective patterned photoresist layer, wherein final vertical stacks of at least one final insulating plate and at least one final dielectric material plate are formed; and
replacing remaining portions of the sacrificial material layers that underlie the final vertical stacks with electrically conductive layers.

2. The method of claim 1, further comprising:
forming memory openings through a region of the alternating stack that is free of the final vertical stacks; and
forming memory opening fill structures in the memory openings, wherein each of the memory opening fill structures comprises a respective vertical stack of memory elements and a respective vertical semiconductor channel.

3. The method of claim 1, further comprising:
forming backside trenches through the alternating stack; and
performing an isotropic etch process that etches a material of the sacrificial material layers selective to a material of the insulating layers by introducing an isotropic etchant into the backside trenches to form backside recesses.

4. The method of claim 3, further comprising depositing an electrically conductive material in the backside recesses through the backside trenches.

5. The method of claim 1, further comprising:
forming a dielectric material portion having a stepped bottom surface directly on the final vertical stacks of at least one final insulating plate and at least one final dielectric material plate; and
forming layer contact via cavities through the dielectric material portion by performing an anisotropic etch process that includes a first etch step that etches a material of the dielectric material portion selective to at least one material within the final vertical stacks which is used as an etch stop.

6. The method of claim 5, wherein:
the final vertical stacks are laterally spaced from the backside trenches; and
the final dielectric material plates comprise a same material as a material of the sacrificial material layers after replacement of the remaining portions of the sacrificial material layers that underlie the final vertical stacks with the electrically conductive layers.

7. The method of claim 6, wherein the first etch step etches the material of the dielectric material portion selective to a material of the final dielectric material plates which is used as an etch stop.

8. The method of claim 7, wherein the anisotropic etch process further comprises at least one second etch step that etches a material of the final dielectric material plates selective to a material of the final insulating plates, and at least one third etch step that etches the material of the final insulating plates selective to the material of the final dielectric material plates or selective to a material of the electrically conductive layers.

9. The method of claim 5, further comprising replacing the final dielectric material plates with electrically conductive material plates concurrently with replacement of the sacrificial material layers with the electrically conductive layers, wherein the first etch step etches the material of the dielectric material portion selective to a material of the electrically conductive material plates which is used as an etch stop.

10. The method of claim 9, wherein the anisotropic etch process further comprises at least one second etch step that etches the material of the electrically conductive material plates selective to a material of the final insulating plates, and at least one third etch step that etches the material of the final insulating plates selective to the material of the electrically conductive material plates and selective to a material of the electrically conductive layers.

11. The method of claim 9, further comprising depositing a dielectric backside trench fill material at least at a peripheral portion of each of the backside trenches, wherein all sidewall surfaces of the electrically conductive material plates are in contact with the dielectric backside trench fill material.

12. The method of claim 1, wherein each of the final vertical stacks comprises a vertically alternating sequence of a respective plurality of final insulating plates and a respective plurality of final dielectric material plates.

13. The method of claim 1, wherein:
a first portion of an alternating stack of the insulating layers and the electrically conductive layers comprises a first tier;
a second portion of the alternating stack of the insulating layers and the electrically conductive layers comprises a second tier located over the first tier; and
each of the vertical stacks in the first tier comprises a different number of the insulating plates and the spacer material plates than each of the vertical stacks in the second tier.

14. The method of claim 2, further comprising forming a first memory array region and a second memory array region that are laterally spaced apart by a staircase region containing the stepped surfaces, wherein the memory opening fill structures are located within the first memory array region and the second memory array region,
wherein the electrically conductive layers have a respective bridge region having a respective strip width within the staircase region, and the electrically conductive layers have a respective uniform width greater than the strip width in the first memory array region, the second memory array region, and portions of the staircase region located outside the bridge region.

15. A semiconductor structure, comprising:
an alternating stack of insulating layers and electrically conductive layers, wherein the alternating stack comprises stepped surfaces;
vertical stacks of at least one insulating plate and at least one spacer material plate, wherein each of the vertical stacks is located on a respective horizontal surface segment of the stepped surfaces;
a dielectric material portion having a stepped bottom surface and contacting each of the vertical stacks; and
layer contact via structures vertically extending through the dielectric material portion and a respective vertical stack of the vertical stacks and contacting a respective electrically conductive layer of the electrically conductive layers.

16. The semiconductor structure of claim 15, further comprising:
a first memory array region and a second memory array region that are laterally spaced apart by a staircase region containing the stepped surfaces;
memory opening fill structures each comprising a respective vertical stack of memory elements and a respective vertical semiconductor channel vertically extending through the alternating stack and located within the first memory array region and the second memory array region, wherein the electrically conductive layers have a respective bridge region having a respective strip width within the staircase region, and the electrically conductive layers have a respective uniform width greater than the strip width in the first memory array region, the second memory array region, and portions of the staircase region located outside the bridge region; and
a backside trench fill structure comprising a dielectric backside trench fill material at least in a peripheral portion of the backside trench fill structure.

17. The semiconductor structure of claim 16, wherein:
the spacer material plates comprise a dielectric material having a different material composition than the insulating plates and the insulating layers; and
each sidewall of the insulating plates and the spacer material plates is laterally offset from the dielectric backside trench fill material.

18. The semiconductor structure of claim 16, wherein:
the spacer material plates and the electrically conductive layers comprise a same electrically conductive material; and
each sidewall of the insulating plates and the spacer material plates is in direct contact with the dielectric backside trench fill material.

19. The semiconductor structure of claim 15, wherein each of the vertical stacks comprises a vertically alternating sequence of a respective plurality of insulating plates and a respective plurality of spacer material plates.

20. The semiconductor structure of claim 15, wherein:
a first portion of the alternating stack of insulating layers and electrically conductive layers comprises a first tier;
a second portion of the alternating stack of insulating layers and electrically conductive layers comprises a second tier located over the first tier; and
each of the vertical stacks in the first tier comprises a different number of the insulating plates and the spacer material plates than each of the vertical stacks in the second tier.
